(19) United States
(12) Patent Application Publication
(10) Pub. No.: US 2024/0427248 A1
(43) Pub. Date: Dec. 26, 2024

(54) RESIST TOPCOAT COMPOSITION AND METHOD OF FORMING PATTERNS USING THE COMPOSITION

(71) Applicant: SAMSUNG SDI CO., LTD., Yongin-si (KR)

(72) Inventors: Kyoungjin HA, Suwon-si (KR); Ran NAMGUNG, Suwon-si (KR); Hyeon PARK, Suwon-si (KR); Daeseok SONG, Suwon-si (KR); Minsoo KIM, Suwon-si (KR)

(21) Appl. No.: 18/734,967

(22) Filed: Jun. 5, 2024

(30) Foreign Application Priority Data
Jun. 13, 2023 (KR) 10-2023-0075624

(51) Int. Cl. G03F 7/11; C08F 220/28; C09D 133/16

(52) U.S. Cl. CPC G03F 7/11; C08F 220/281; C08F 220/282; C09D 133/16

(57) ABSTRACT

A resist topcoat composition and a method of forming (or providing) patterns utilizing the resist topcoat composition are provided. The resist topcoat composition includes a copolymer including a first structural unit represented by Chemical Formula M-1, a second structural unit represented by Chemical Formula M-2, and a third structural unit represented by Chemical Formula M-3A or Chemical Formula M-3B; and a solvent. Details about the above chemical formulas are as described in the specification.

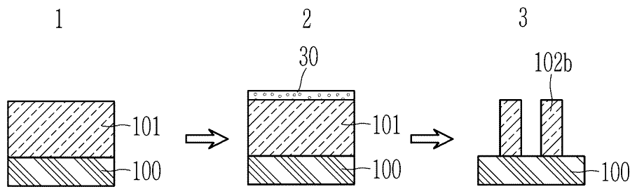

### CROSS-REFERENCE TO RELATED APPLICATION

The present application claims priority to and the benefit of Korean Patent Application No. 10-2023-0075624, filed on Jun. 13, 2023, in the Korean Intellectual Property Office, the entire content of which is incorporated herein by reference.

### BACKGROUND

### 1. Field

This disclosure relates to a resist topcoat composition, and a method of forming (or providing) patterns utilizing the same.

### 2. Description of the Related Art

Recently, the semiconductor industry has developed an ultrafine technique to create patterns of several to several tens of nanometers (e.g., pattens in nanometer scale). Such ultrafine technique relies on (essentially needs) effective photolithographic processes.

Related art photolithographic processes involve forming (or providing) a material layer on a semiconductor substrate, coating a photoresist film thereon, exposing and developing photoresist film to form (or provide) a photoresist pattern, and then etching the material layer utilizing the photoresist pattern as a mask.

As photolithography processes develop, a degree of pattern integration is increasing, and materials and technologies for solving various problems occurring in this process are desired or required.

For example, if (e.g., when) extreme ultraviolet (EUV) is irradiated to (onto) the photoresist, because of the large energy per photon, there may be a region where lots of or little light is randomly or undesirably irradiated, which is a photo shot noise, or an EUV absorption difference between top and bottom of the photoresist may exist, which may cause pattern distribution deterioration such as increase in roughness (LER: line edge roughness, LWR: line width roughness) and/or uniformity (IPU (in-point uniformity)) of the patterns. In order to improve or reduce this pattern distribution deterioration, technology development is desired or required.

### SUMMARY

An aspect according to one or more embodiments is directed toward a resist topcoat composition capable of reducing pattern distribution (e.g., variation) by preventing or reducing pattern deterioration.

An aspect according to one or more embodiments is directed toward a method of forming (or providing) patterns utilizing the resist topcoat composition.

According to some embodiments, a resist topcoat composition includes a copolymer including a first structural unit represented by Chemical Formula M-1, a second structural unit represented by Chemical Formula M-2, and a third structural unit represented by Chemical Formula M-3A or Chemical Formula M-3B; and a solvent.

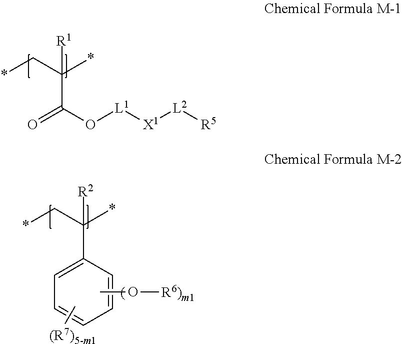

wherein, in Chemical Formula M-1 and Chemical Formula M-2,
R¹ and R² may each independently be hydrogen or a substituted or unsubstituted C1 to C10 alkyl group,
L¹ and L² may each independently be a single bond, a substituted or unsubstituted C1 to C10 alkylene group, and/or a (e.g., any suitable) combination thereof,
X¹ may be a single bond, —O—, —S—, —S(O)—, —S(O)₂—, —C(O)—, —C(═O)O—, —OC(═O)—, —OC(═O)O—, —NR^{a}—, wherein, R^{a} may be hydrogen, deuterium, or a substituted or unsubstituted C1 to C10 alkyl group, and/or a (e.g., any suitable) combination thereof,
R⁵ may be hydrogen, fluorine, a hydroxy group, a substituted or unsubstituted C1 to C20 alkyl group, and/or a (e.g., any) suitable combination thereof,
R⁶ may be hydrogen, or C(═O)R^{b},
R^{b} may be a substituted or unsubstituted C1 to C10 alkyl group,
at least one of R⁵, L¹, or L² may include fluorine and a hydroxy group,
R⁷ may be hydrogen, a halogen, a hydroxy group, a substituted or unsubstituted C1 to C10 alkyl group, and/or a (e.g., any suitable) combination thereof, and
m1 may be an integer selected from 1 to 4,

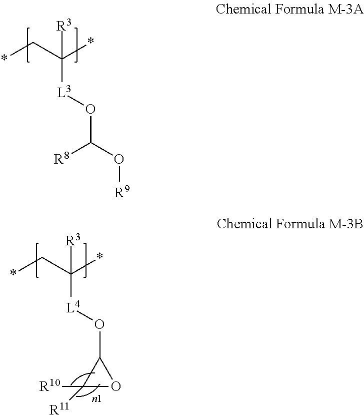

wherein, in Chemical Formula M-3A and Chemical Formula M-3B,
R³ may be hydrogen or a substituted or unsubstituted C1 to C10 alkyl group,
L³ and L⁴ may each independently be a single bond, a substituted or unsubstituted C1 to C10 alkylene group, a substituted or unsubstituted C6 to C20 arylene group, and/or a (e.g., any suitable) combination thereof,
R⁸ to R¹¹ may each independently be hydrogen, a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C20 aryl group, and/or a (e.g., any suitable) combination thereof,
n1 may be an integer selected from 1 to 6, and
* may be a linking point.

In some embodiments, the first structural unit may be represented by Chemical Formula 1.

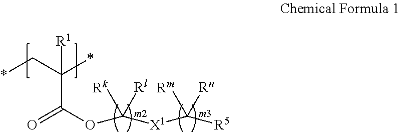

In Chemical Formula 1,
R¹ may be hydrogen or a substituted or unsubstituted C1 to C10 alkyl group,
R^{k}, R^{l}, R^{m}, Rⁿ, and R⁵ may each independently be hydrogen, fluorine, a hydroxy group, a substituted or unsubstituted C1 to C20 alkyl group, and/or a (e.g., any suitable) combination thereof,
m2 and m3 may each independently be an integer selected from 1 to 10,
X¹ may be a single bond, —O—, —S—, —S(O)—, —S(O)₂—, —C(O)—, —C(═O)O—, —OC(═O)—, —OC(═O)O—, —NR^{a}—, wherein, R^{a} may be hydrogen, deuterium, or a substituted or unsubstituted C1 to C10 alkyl group, and/or a (e.g., any suitable) combination thereof, and
at least one of R^{k}, R^{l}, R^{m}, Rⁿ, or R⁵ may include fluorine and a hydroxy group.

In some embodiments, at least one of R^{m}, Rⁿ, or R⁵ in Chemical Formula 1 may include a fluorine group and a hydroxy group.

In some embodiments, at least one of R^{m} or Rⁿ in Chemical Formula 1 may be fluorine or a C1 to C10 alkyl group substituted with at least one fluorine, and R⁵ may be a hydroxy group or a C1 to C10 alkyl group substituted with at least one hydroxy group.

In some embodiments, at least one of R^{m} or Rⁿ in Chemical Formula 1 may be a hydroxy group or a C1 to C10 alkyl group substituted with at least one hydroxy group, and R⁵ may be fluorine or a C1 to C10 alkyl group substituted with at least one fluorine.

In some embodiments, R^{m} in Chemical Formula 1 may be a hydroxy group or a C1 to C10 alkyl group substituted with at least one hydroxy group, Rⁿ may be fluorine or a C1 to C10 alkyl group substituted with at least one fluorine, and R⁵ may be a hydroxy group, fluorine, or a C1 to C10 alkyl group substituted with one or more fluorine groups or one or more hydroxy groups.

In some embodiments, at least one of R^{m} or Rⁿ in Chemical Formula 1 may be fluorine or a C1 to C10 alkyl group substituted with at least one fluorine, and R⁵ may be a hydroxy group, or a C1 to C5 alkyl group substituted with at least one of one or more hydroxy groups or one or more C1 to C5 fluoroalkyl groups. For example, R⁵ may be a C1 to C5 alkyl group substituted with one or more hydroxy groups and/or substituted with one or more C1 to C5 fluoroalkyl groups.

In some embodiments, the first structural unit may be any one (e.g., one) selected from among structures in Group I.

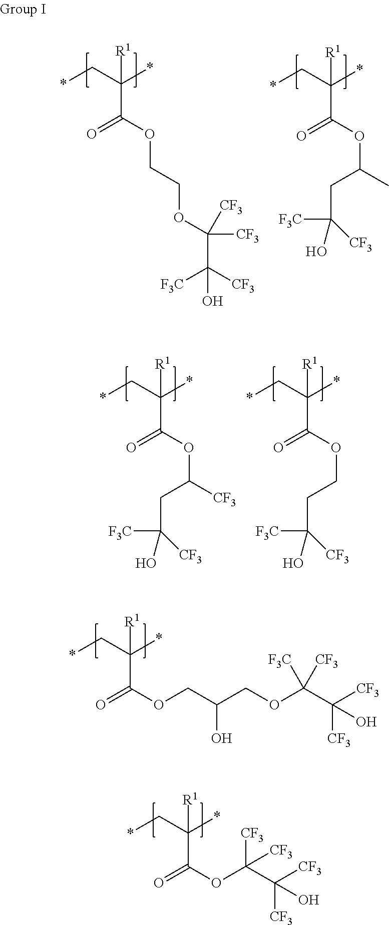

In Group I, R¹ may each independently be hydrogen or a methyl group, and may be a linking point.

In some embodiments, the second structural unit may be represented by any one (e.g., one) selected from among Chemical Formula 2-1 to Chemical Formula 2-4.

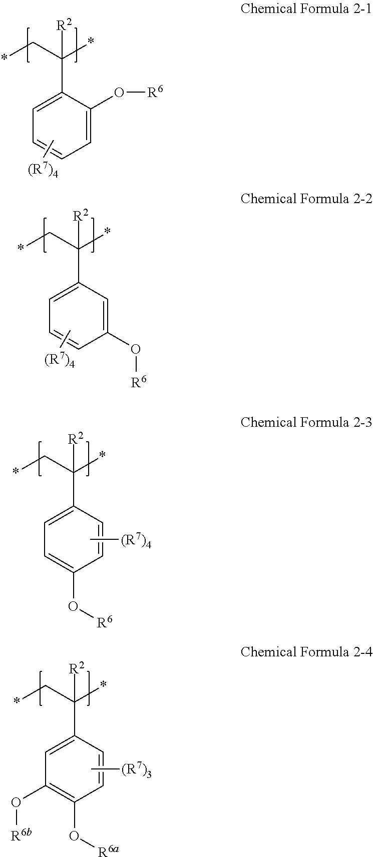

In Chemical Formula 2-1 to Chemical Formula 2-4,
R² may be hydrogen or a methyl group,
R⁶, R^{6a}, and R^{6b} may each independently be hydrogen, or C(═O)R^{b},
R^{b} may be a substituted or unsubstituted C1 to C5 alkyl group,
R⁷ may each independently be hydrogen, a halogen, a hydroxy group, a substituted or unsubstituted C1 to C10 alkyl group, and/or a (e.g., any suitable) combination thereof, and
* may be a linking point.

In some embodiments, at least one of R⁷s may be a halogen.

In some embodiments, at least one of R⁷s may be an iodine group.

The second structural unit may be any one (e.g., one) selected from among structures in Group 11.

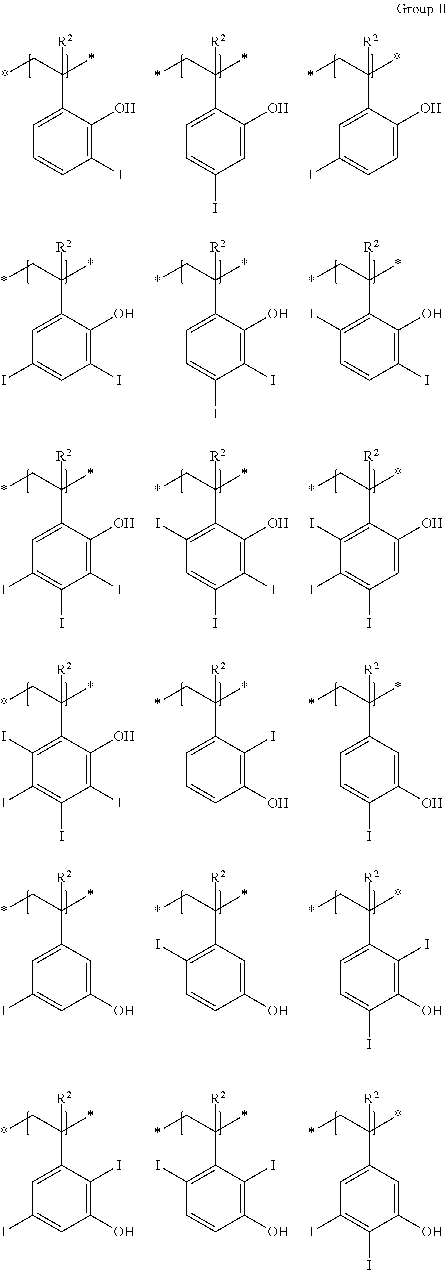

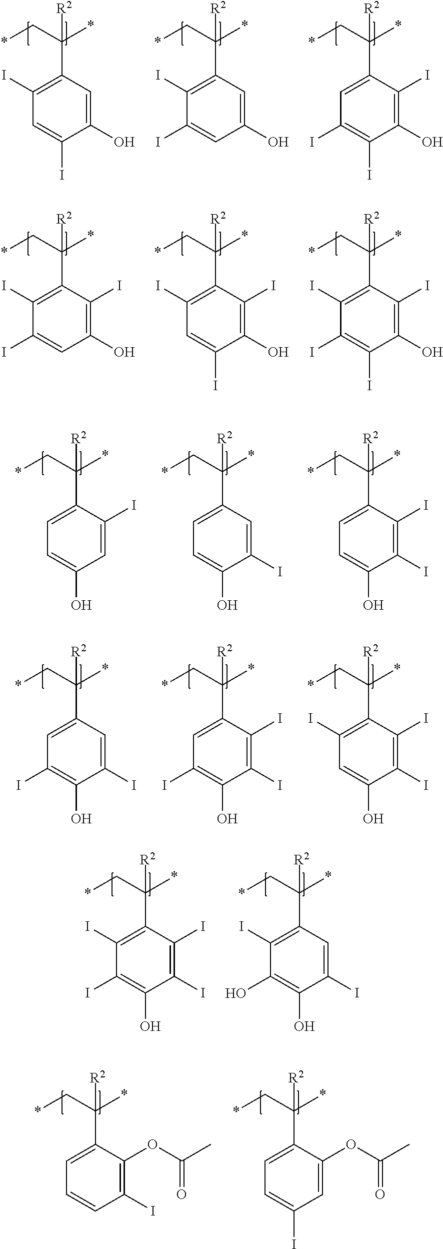

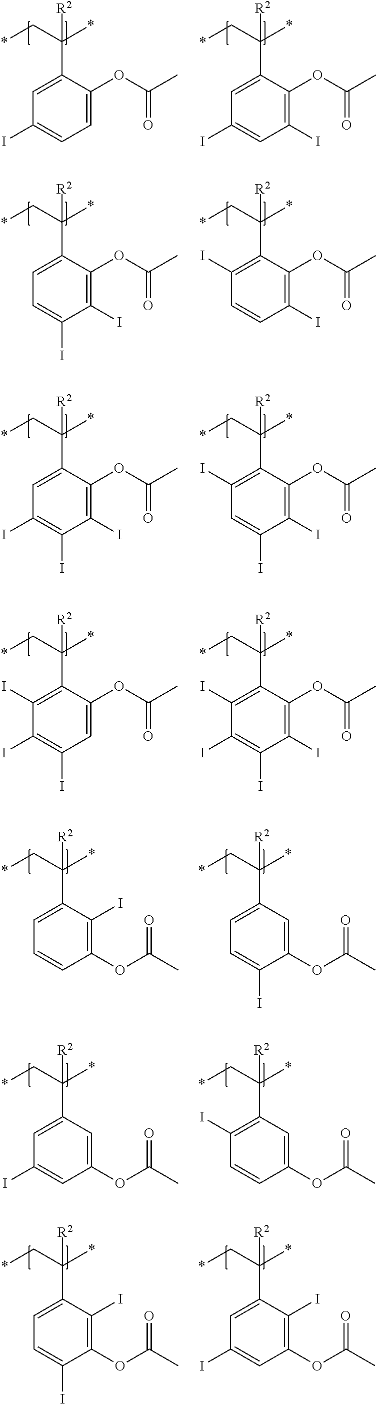

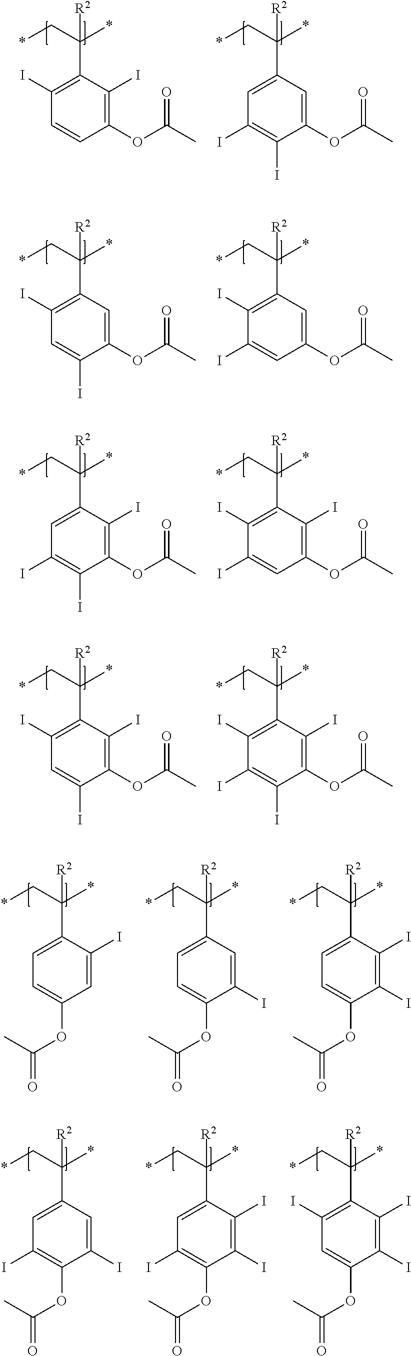

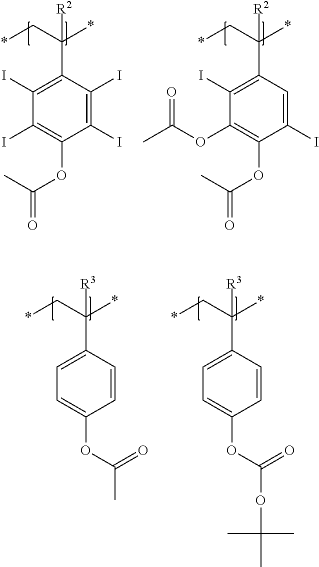

In Group II, R² may each independently be hydrogen or a methyl group, and * may be a linking point.

In some embodiments, L³ and L⁴ may each independently be a single bond, a substituted or unsubstituted C1 to C5 alkylene group, or a substituted or unsubstituted C6 to C12 arylene group, and

R⁸ to R¹⁵ may each independently be hydrogen, a substituted or unsubstituted C1 to C10 alkyl group, or a substituted or unsubstituted C6 to C12 aryl group.

In some embodiments, the third structural unit may be any one (e.g., one) selected from among structures in Group Ill.

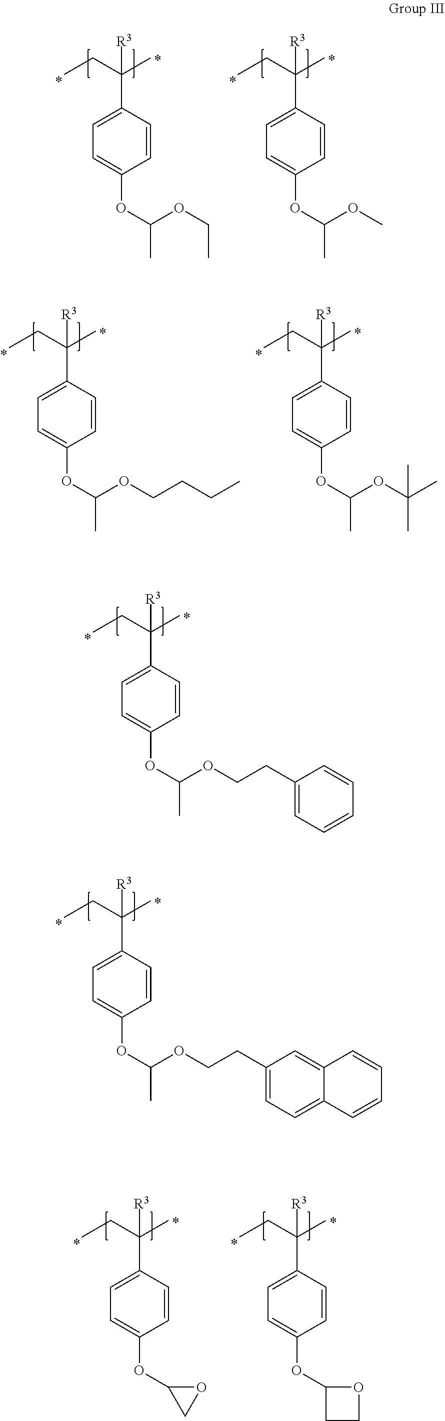

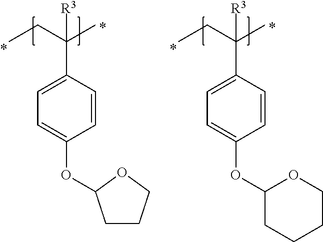

In Group III,
R³ may be hydrogen or a methyl group, and * may be a linking point.

In some embodiments, the copolymer according to some embodiments may include about 30 mol % to about 95 mol % of the first structural unit, about 1 mol % to about 20 mol % of the second structural unit, and about 5 mol % to about 50 mol % of the third structural unit, based on a total 100 mol % of the copolymer.

In some embodiments, the copolymer may have a weight average molecular weight of about 1,000 g/mol to about 50,000 g/mol.

In some embodiments, the copolymer according to some embodiments may be included in an amount of 0.1 wt % to 10 wt % based on a total weight of the resist topcoat composition.

In some embodiments, the copolymer may be any one (e.g., one) selected from among or may include at least one (e.g., one or more) selected from among those listed in Group IV.

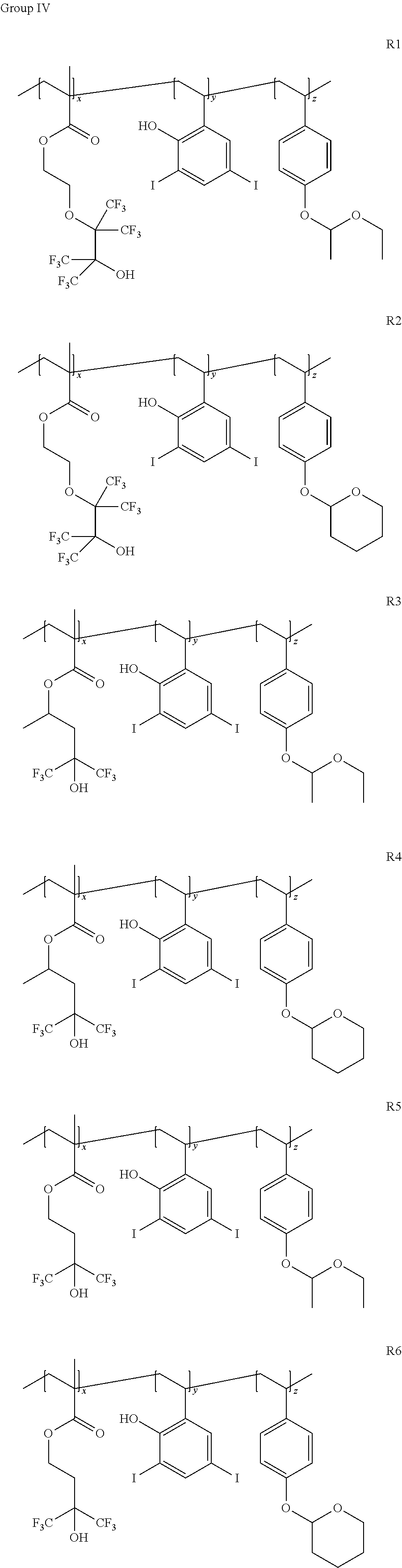

In Group IV, x:y:z may be 60:10:30, 60:20:20, 66:10:24, 69:12:19, 70:10:20, 70:20:10 or 80:10:10.

In some embodiments, the solvent may be an ether-based solvent represented by Chemical Formula 4.

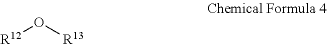

In Chemical Formula 4,
R¹² and R¹³ may each independently be a substituted or unsubstituted C3 to C20 alkyl group.

In some embodiments, the ether-based solvent may be any one (e.g., one) selected from among or may include at least one (e.g., one or more) selected from among diisopropylether, dipropylether, diisoamylether, diamylether, dibutylether, diisobutylether, di-sec-butylether, dihexylether, bis(2-ethylhexyl)ether, didecylether, diundecylether, didodecylether, ditetradecylether, hexadecylether, butylmethylether, butylethylether, butylpropylether, tert-butylmethylether, tert-butylethylether, tert-butylpropylether, di-tert-butylether, cyclopentylmethylether, cyclohexylmethylether, cyclopentylethylether, cyclohexylethylether, cyclopentylpropylether, cyclopentyl-2-propylether, cyclohexylpropylether, cyclohexyl-2-propylether, cyclopentylbutylether, cyclopentyl-tert-butylether, cyclohexylbutylether, cyclohexyl-tert-butylether, 2-octanone, 4-heptanone, and/or a (e.g., any suitable) combination thereof.

According to some embodiments, a method of forming (or providing) patterns includes coating and heating a photoresist composition on a substrate to form (or provide) a photoresist film, coating and heating the aforementioned resist topcoat composition on the photoresist film to form (or provide) a topcoat, and exposing and developing the topcoat and the photoresist film to form (or provide) a resist pattern.

The resist topcoat composition according to some embodiments may remove excessive activated acid from the top of the photoresist, if (e.g., when) exposed with EUV, to prevent or reduce the pattern distribution deterioration such as roughness (LER, LWR) or IPU of the patterns due to EUV absorption difference between top and bottom of a photoresist layer, and thereby improving the pattern distribution and also significantly improving IPU of pillar patterns, desirably contributing to forming (or providing) fine patterns of the photoresist.

### BRIEF DESCRIPTION OF DRAWING

The above and other aspects, features, and enhancements of certain embodiments of the disclosure will be more apparent from the following description taken in conjunction with the accompanying drawing, in which:

The drawing is a schematic view for explaining a method of forming (or providing) patterns utilizing a resist topcoat composition according to some embodiments.

### DETAILED DESCRIPTION

Example embodiments of the present disclosure will hereinafter be described in more detail, and may be easily performed by a person skilled in the art. However, this disclosure may be embodied in many different forms and is not construed as limited to the example embodiments set forth herein.

In the drawing, the thickness of layers, films, panels, regions, and/or the like, may be exaggerated for clarity and like reference numerals designate like elements throughout, and duplicative descriptions thereof may not be provided in the specification. It will be understood that if (e.g., when) an element such as a layer, film, region, or substrate is referred to as being “on” another element, it can be directly on the other element or intervening elements may also be present. In contrast, if (e.g., when) an element is referred to as being “directly on” another element, there are no intervening elements present.

As used herein, if (e.g., when) a definition is not otherwise provided, the term “substituted” refers to replacement of at least one a hydrogen atom of a substituent or a compound by a substituent selected from among a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamoyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C6 to C30 allyl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and/or a (e.g., any suitable) combination thereof.

As used herein, if (e.g., when) a definition is not otherwise provided, the term “hetero” refers to one including 1 to 10 heteroatoms selected from among N, O, S, and P.

Unless otherwise specified in the present specification, the weight average molecular weight is measured by dissolving a powder sample in tetrahydrofuran (THF) and then measured utilizing 1200 series Gel Permeation Chromatography (GPC) of Agilent Technologies (column is Shodex Company LF-804, standard sample is Shodex company polystyrene).

In addition, unless otherwise defined in the specification, “*” indicates a linking point of a structural unit or a compound moiety of a compound.

Hereinafter, a resist topcoat composition according to some embodiments is described.

The present disclosure relates to a photoresist topcoat composition capable of improving in-point uniformity (IPU) of contact hole (C/H) patterns, line edge roughness (LER)/line width roughness (LWR) of line and space (US) patterns, and/or IPU of pillar patterns by improving sensitivity of a photoresist during the fine pattern-forming (or providing) process of photolithography utilizing high-energy rays such as EUV (extreme ultraviolet; wavelength: about 13.5 nm) and/or the like and concurrently (e.g., simultaneously), selectively reducing an acid concentration of the upper portion of the photoresist layer and a method of forming (or providing) photoresist patterns by utilizing this topcoat.

In some embodiments, the resist topcoat composition according to some embodiments includes a copolymer including a first structural unit represented by Chemical Formula M-1, a second structural unit represented by Chemical Formula M-2, and a third structural unit represented by Chemical Formula M-3A or Chemical Formula M-3B; and a solvent.

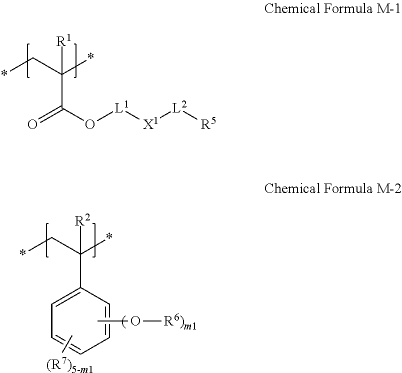

In Chemical Formula M-1 and Chemical Formula M-2,
R¹ and R² may each independently be hydrogen or a substituted or unsubstituted C1 to C10 alkyl group,
L¹ and L² may each independently be a single bond, a substituted or unsubstituted C1 to C10 alkylene group, and/or a (e.g., any suitable) combination thereof,
X¹ may be a single bond, —O—, —S—, —S(O)—, —S(O)₂—, —C(O)—, —C(═O)O—, —OC(═O)—, —OC(═O)O—, —NR^{a}— (wherein, R^{a} may be hydrogen, deuterium, or a substituted or unsubstituted C1 to C10 alkyl group), and/or a (e.g., any suitable) combination thereof,
R⁵ may be hydrogen, fluorine, a hydroxy group, a substituted or unsubstituted C1 to C20 alkyl group, and/or a (e.g., any suitable) combination thereof,
R⁶ may be hydrogen, or C(═O)R^{b},
R^{b} may be a substituted or unsubstituted C1 to C10 alkyl group,
at least one of R⁵, L¹ or L² may include fluorine and a hydroxy group, for example, at least one of R⁵, L¹ or L² may include fluorine and at least one of R⁵, L¹ or L² may include a hydroxy group,
R⁷ may be hydrogen, a halogen, a hydroxy group, a substituted or unsubstituted C1 to C10 alkyl group, and/or a (e.g., any suitable) combination thereof, and
m1 may be an integer selected from 1 to 4,

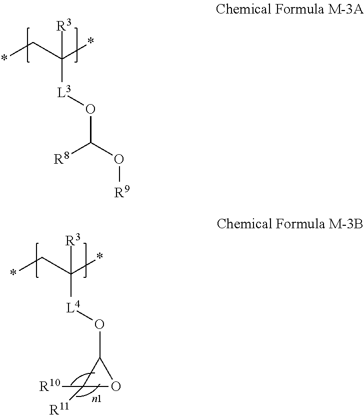

In Chemical Formula M-3A and Chemical Formula M-3B,
R³ may be hydrogen or a substituted or unsubstituted C1 to C10 alkyl group,
L³ and L⁴ may each independently be a single bond, a substituted or unsubstituted C1 to C10 alkylene group, a substituted or unsubstituted C6 to C20 arylene group, and/or a (e.g., any suitable) combination thereof,
R⁸ to R¹¹ may each independently be hydrogen, a substituted or unsubstituted C1 to C20 alkyl group, a substituted or unsubstituted C2 to C20 alkenyl group, a substituted or unsubstituted C2 to C20 alkynyl group, a substituted or unsubstituted C6 to C20 aryl group, and/or a (e.g., any suitable) combination thereof,
n1 may be an integer selected from 1 to 6, and
* may be a linking point.

The photoresist topcoat composition according to some embodiments may be coated on top of a photoresist film to significantly improve LER/LWR of L/S patterns, IPU of C/H patterns, and/or IPU of pillar patterns as well as increase sensitivity of the photoresist.

The first structural unit included in the copolymer of the composition has characteristics of having almost no reactivity with the photoresist but having suitable solubility (e.g., being well dissolved) in a solvent and thus may protect the photoresist, while minimizing or reducing an influence on the photoresist, the second structural unit may increase EUV absorption to improve sensitivity, the third structural unit modifies the surface of the photoresist at the top of the photoresist layer to be easily soluble in a basic developer, thereby removing or reducing a rounded profile area of the upper layer of the photoresist generated during the exposure process, the development process, and/or controls upper etching during development by reaction with the acid generated from the photoresist to improve IPU or LWR of the pattern to have, e.g., a rectangular shape.

On the other hand, if (e.g., when) the photoresist topcoat composition remains after the development, it may cause scum defects in the L/S patterns or not-open defects in the C/H patterns, resulting in decreased product yield.

However, the photoresist topcoat composition according to some embodiments may be removed during the development process and thus cause no defects in various suitable patterns.

In Chemical Formula M-2, if (e.g., when) m1 is 2 or more, each O—R⁶ may be the same or different from each other.

In Chemical Formula M-2, if (e.g., when) 5-m1 is 2 or more, each R⁷ may be the same or different from each other.

The expression that at least one of R⁵, L¹, or L² includes a fluorine and hydroxy group may include cases where,
R⁵ may be a C1 to C20 alkyl group substituted with at least one fluorine and at least one hydroxy group, or
at least one of L¹ or L² may be a C1 to C10 alkylene group substituted with one or more fluorine and one or more hydroxy groups, or
at least one of L¹ or L² may be a C1 to C10 alkylene group substituted with one or more fluorine, and at least another one of L¹ or L² may be a C1 to C10 alkylene group substituted with one or more hydroxy groups, or
R⁵ may be fluorine, and at least one of L¹ or L² may be a C1 to C10 alkylene group substituted with one or more hydroxy groups, or
R⁵ may be a hydroxy group, and at least one of L¹ or L² may be a C1 to C10 alkylene group substituted with one or more fluorine, or
R⁵ may be a C1 to C10 alkyl group substituted with one or more fluorine and one or more hydroxy groups, or
R⁵ may be a C1 to C10 alkyl group substituted with one or more hydroxy groups and one or more C1 to C10 fluoroalkyl groups.

In some embodiments, the first structural unit may be represented by Chemical Formula 1.

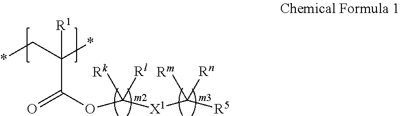

In Chemical Formula 1,
R¹ may be hydrogen or a substituted or unsubstituted C1 to C10 alkyl group,
R^{k}, R^{l}, R^{m}, Rⁿ, and R⁵ may each independently be hydrogen, fluorine, a hydroxy group, a substituted or unsubstituted C1 to C20 alkyl group, and/or a (e.g., any suitable) combination thereof,
m2 and m3 may each independently be an integer selected from 1 to 10,
X¹ may be a single bond, —O—, —S—, —S(O)—, —S(O)₂—, —C(O)—, —C(═O)O—, —OC(═O)—, —OC(═O)O—, —NR^{a}— (wherein, R^{a} is hydrogen, deuterium, or a substituted or unsubstituted C1 to C10 alkyl group), and/or a (e.g., any suitable) combination thereof, and
at least one of R^{k}, R^{l}, R^{m}, Rⁿ, and R⁵ may include fluorine and a hydroxy group, for example, at least one of R^{k}, R^{l}, R^{m}, Rⁿ, or R⁵ may include fluorine and at least one of R^{k}, R^{l}, R^{m}, Rⁿ, or R⁵ may include a hydroxy group.

In Chemical Formula 1, if (e.g., when) m2 is 2 or more, each R^{k} may be the same or different from each other.

In Chemical Formula 1, if (e.g., when) m2 is 2 or more, each R^{l} may be the same or different from each other.

In Chemical Formula 1, if (e.g., when) m3 is 2 or more, each R^{m} may be the same or different from each other.

In Chemical Formula 1, if (e.g., when) m3 is 2 or more, each Rⁿ may be the same or different from each other.

The expression that at least one of R^{k}, R^{l}, R^{m}, Rⁿ, or R⁵ includes a fluorine and hydroxy group may include cases where:
at least one of R^{k}, R^{l}, R^{m}, Rⁿ, or R⁵ may each independently include both a fluorine and hydroxy group, or
at least one of R^{k}, R^{l}, R^{m}, Rⁿ, or R⁵ may each independently include a C1 to C10 alkyl group substituted with one or more fluorine and a C1 to C10 alkyl group substituted with one or more hydroxy groups, or
at least one of R^{k}, R^{l}, R^{m}, Rⁿ, or R⁵ may each independently include C1 to C10 alkyl groups substituted with one or more hydroxy groups and one or more fluorine, or
at least one of R^{k}, R^{l}, R^{m}, Rⁿ, or R⁵ may each independently include a C1 to C5 alkyl group substituted with one or more hydroxy groups and one or more C1 to C5 fluoroalkyl groups, or
at least one of R^{k}, R^{l}, R^{m}, Rⁿ, or R⁵ may be fluorine, and at least one of the rest of R^{k}, R^{l}, R^{m}, Rⁿ, or R⁵ may be a hydroxy group, or
at least one of R^{k}, R^{l}, R^{m}, Rⁿ, or R⁵ is fluorine, and at least one of the rest of R^{k}, R^{l}, R^{m}, Rⁿ, or R⁵ may include a C1 to C10 alkyl group substituted with one or more hydroxy groups, or
at least one of R^{k}, R^{l}, R^{m}, Rⁿ, or R⁵ may be a hydroxy group, and at least one of the rest of R^{k}, R^{l}, R^{m}, Rⁿ, or R⁵ may include a C1 to C10 alkyl group substituted with one or more fluorines, or
at least one of R^{k}, R^{l}, R^{m}, Rⁿ, or R⁵ may be a C1 to C20 alkyl group substituted with one or more fluorine, and at least one of the rest of R^{k}, R^{l}, R^{m}, Rⁿ, or R⁵ may be a C1 to C20 alkyl group substituted with one or more hydroxy groups.

For example, R¹ may be hydrogen or a methyl group,
X¹ may be a single bond, —O—, or —NR^{a}— (wherein, R^{a} is hydrogen, deuterium, or a substituted or unsubstituted C1 to C10 alkyl group), and
R⁵ may be fluorine, a hydroxy group, a C1 to C10 alkyl group substituted with at least one fluorine, or a C1 to C10 alkyl group substituted with at least one hydroxy group.

In some embodiments, in Chemical Formula 1, at least one of R^{m}, Rⁿ, or R⁵ may include a fluorine and a hydroxy group.

In some embodiments, in Chemical Formula 1, at least one of R^{m} or Rⁿ may be fluorine or a C1 to C10 alkyl group substituted with at least one fluorine, and R⁵ may be a hydroxy group or a C1 to C10 alkyl group substituted with at least one hydroxy group.

In some embodiments, in Chemical Formula 1, at least one of R^{m} or Rⁿ may be a hydroxy group or a C1 to C10 alkyl group substituted with at least one hydroxy group, and R⁵ may be fluorine or a C1 to C10 alkyl group substituted with at least one fluorine.

In some embodiments, in Chemical Formula 1, R^{m} may be a hydroxy group or a C1 to C10 alkyl group substituted with at least one hydroxy group, Rⁿ may be fluorine or a C1 to C10 alkyl group substituted with at least one fluorine, and R⁵ may be a hydroxy group, fluorine, or a C1 to C10 alkyl group substituted with at least one of fluorine or hydroxy groups.

In some embodiments, in Chemical Formula 1, at least one of R^{m} or Rⁿ may be fluorine or a C1 to C10 alkyl group substituted with at least one fluorine, and R⁵ may be a hydroxy group or a C1 to C5 alkyl group substituted with at least one of a hydroxy group or a C1 to C5 fluoroalkyl group.

For example, the first structural unit may be any one (e.g., one) selected from among structures in Group I.

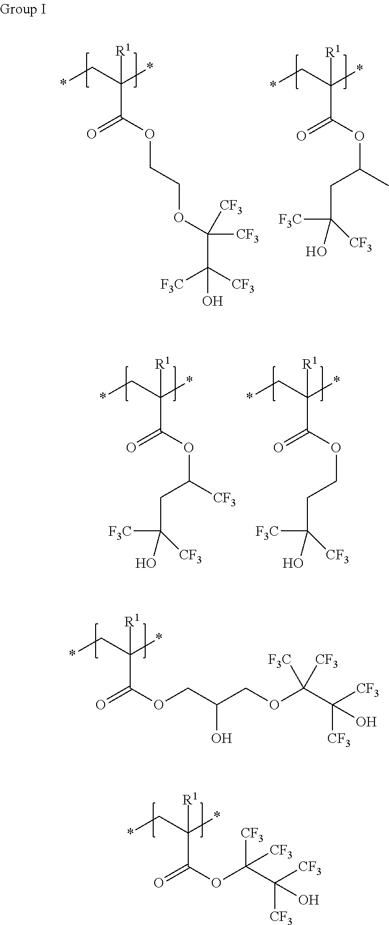

In Group I,
R¹ may each independently be hydrogen or a methyl group, and * may be a linking point.

In some embodiments, the second structural unit may be represented by any one selected from among Chemical Formula 2-1 to Chemical Formula 2-4.

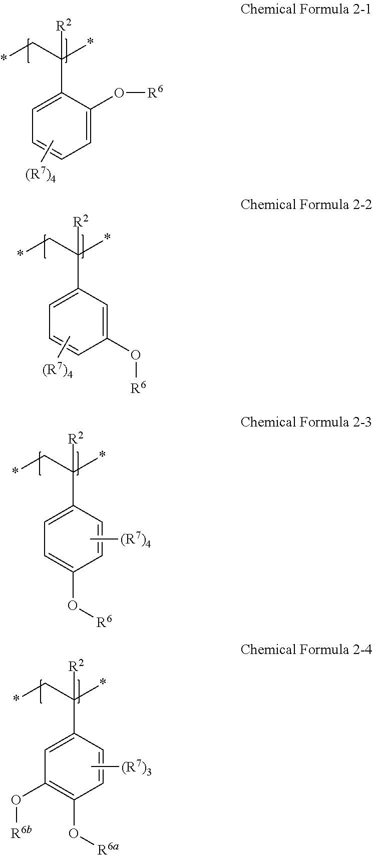

In Chemical Formula 2-1 to Chemical Formula 2-4,
R² may be hydrogen or a methyl group,
R⁶, R^{6a}, and R^{6b} may each independently be hydrogen, or C(═O)R^{b},
R^{b} may be a substituted or unsubstituted C1 to C5 alkyl group,
R⁷ may be each independently hydrogen, a halogen, a hydroxy group, a substituted or unsubstituted C1 to C10 alkyl group, and/or a (e.g., any suitable) combination thereof, and
* may be a linking point.

In Chemical Formula 2-1 to Chemical Formula 2-4, each R⁷ may be different from or the same as each other.

As an example, at least one of R⁷ may be a halogen.

In some embodiments, at least one of R⁷ may be an iodine group.

If (e.g., when) the second structural unit includes an iodine group, sensitivity can be further improved.

For example, the second structural unit may be any one (e.g., one) selected from among structures in Group II.

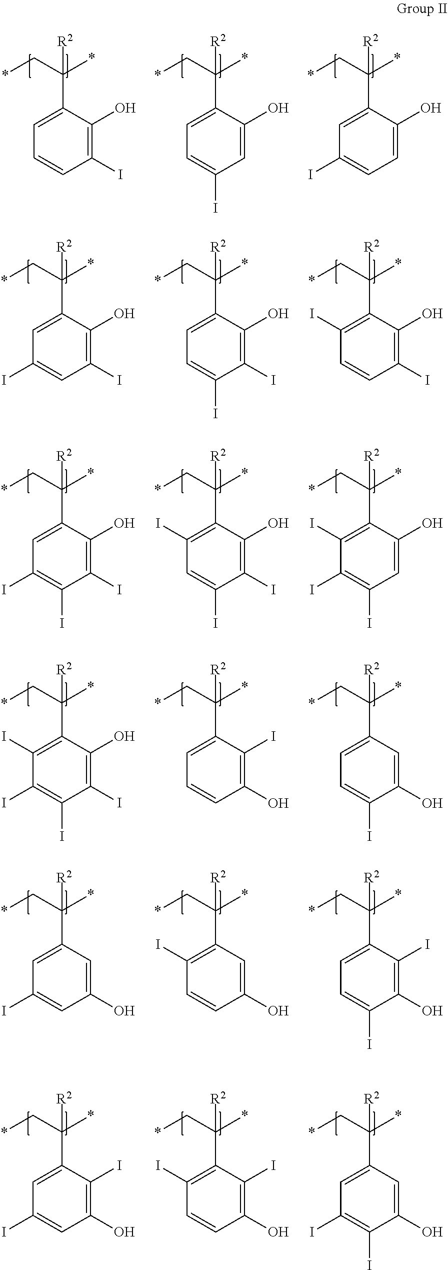

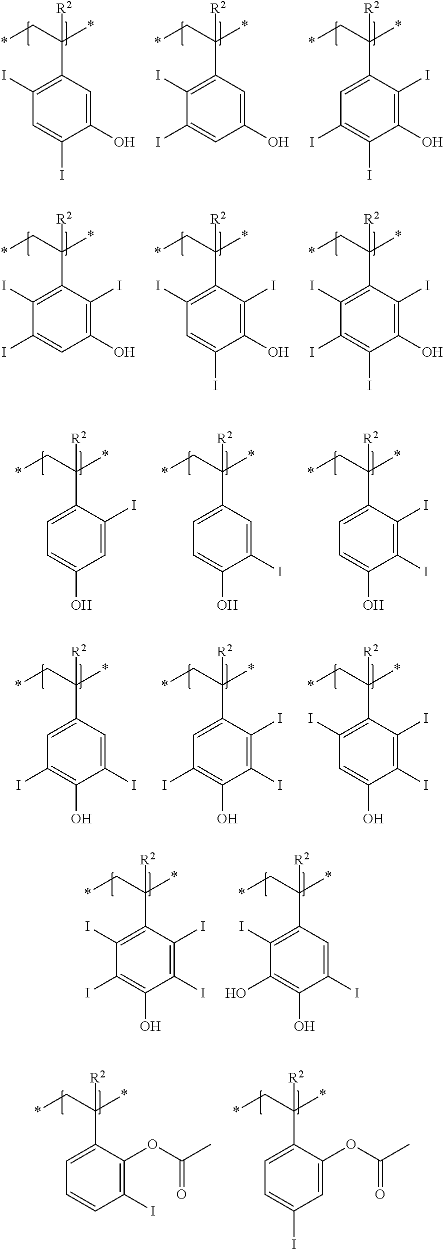

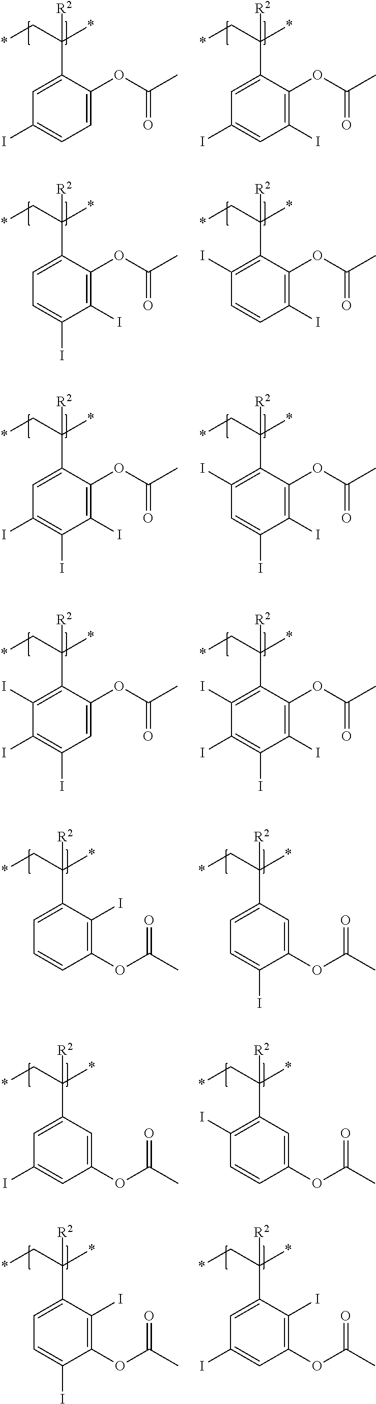

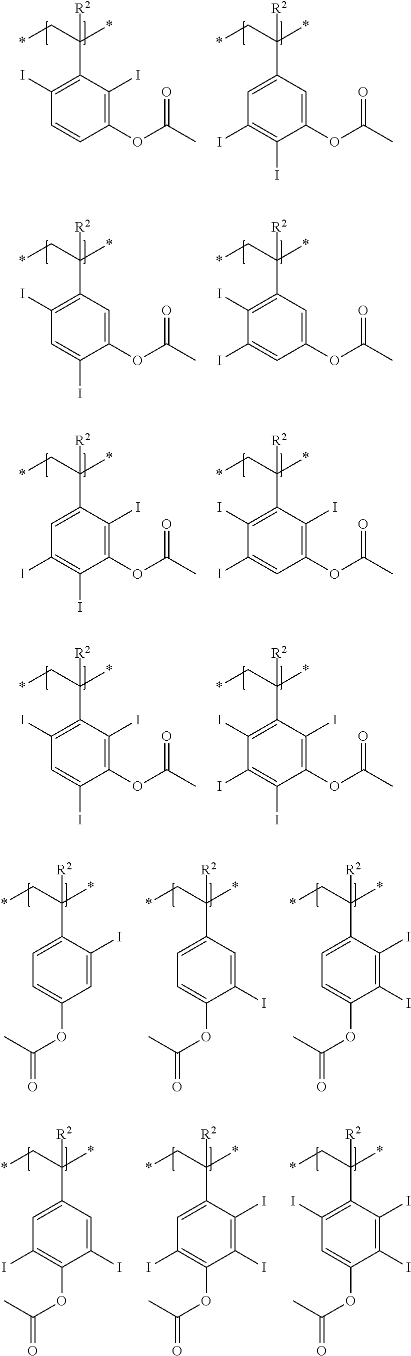

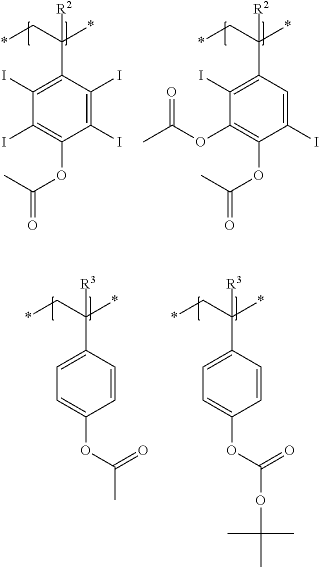

In Group II,
R² may each independently be hydrogen or a methyl group, and * may be a linking point.

For example, L³ and L⁴ may each independently be a single bond, a substituted or unsubstituted C1 to C5 alkylene group, or a substituted or unsubstituted C6 to C12 arylene group, and
R⁸ to R¹¹ may each independently be hydrogen, a substituted or unsubstituted C1 to C10 alkyl group, or a substituted or unsubstituted C6 to C12 aryl group.

The third structural unit may be any one (e.g., one) selected from among structures in Group III.

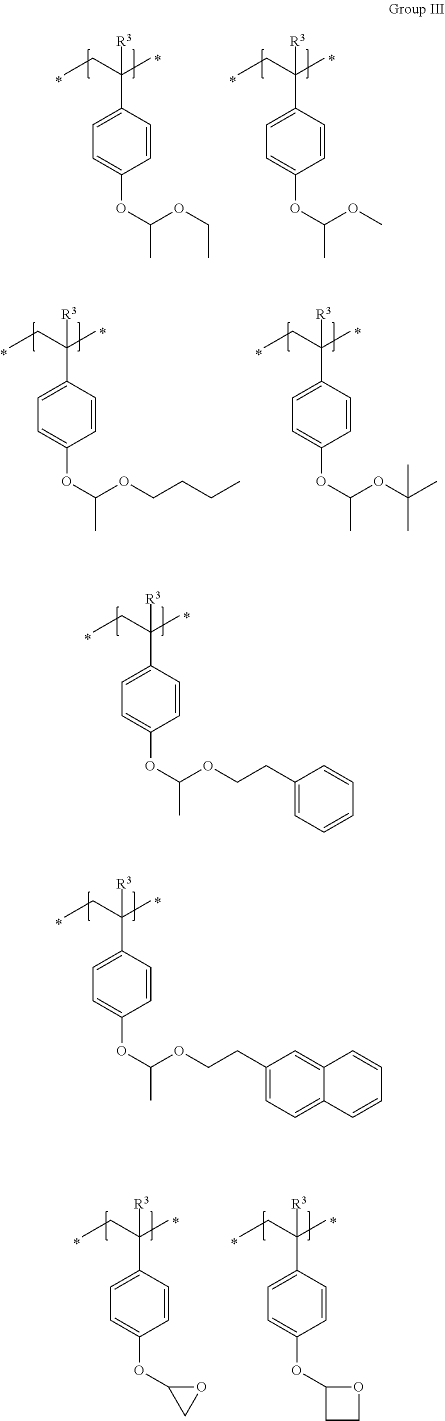

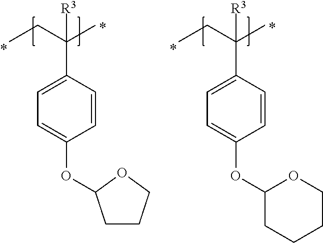

In Group III,
R³ may be hydrogen or a methyl group, and * may be a linking point.

The copolymer may include about 30 mol % to about 95 mol % of the first structural unit, about 1 mol % to about 30 mol % of the second structural unit, and about 1 mol % to about 40 mol % of the third structural unit.

In some embodiments, the copolymer may include about 55 mol % to about 90 mol % of the first structural unit, about 5 mol % to about 30 mol % of the second structural unit, and about 5 mol % to about 30 mol % of the third structural unit. In some embodiments, the copolymer may include about 60 mol % to about 85 mol % of the first structural unit, about 5 mol % to about 20 mol % of the second structural unit, and about 5 mol % to about 25 mol % of the third structural unit.

If (e.g., when) the mole ratio of each structural unit included in the copolymer is within the above ranges, the solubility in organic solvents is improved and the pattern can be uniformly (substantially uniformly) coated.

The copolymer may have a weight average molecular weight (Mw) of about 1,000 g/mol to about 50,000 g/mol. For example, it may have a weight average molecular weight of about 2,000 g/mol to about 30,000 g/mol, or about 3,000 g/mol to about 20,000 g/mol, but the present disclosure is not limited thereto. If (e.g., when) the weight average molecular weight of the copolymer is within the above ranges, a carbon content (e.g., amount) and solubility in a solvent of the resist topcoat composition including the copolymer may be improved or optimized.

The copolymer may be included in an amount of about 0.1 wt % to about 10 wt % based on a total weight of the resist topcoat composition. Within the above range, the resist topcoat may be easily removed.

The solvent may be an ether-based solvent represented by Chemical Formula 4.

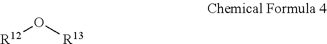

In Chemical Formula 4,
R¹² and R¹³ may each independently be a substituted or unsubstituted C3 to C20 alkyl group.

For example, the ether-based solvent may be any one or may include at least one selected from among diisopropyl ether, dipropyl ether, diisoamyl ether, diamyl ether, dibutyl ether, diisobutyl ether, di-sec-butyl ether, dihexyl ether, bis(2-ethylhexyl) ether, didecyl ether, diundecyl ether, didodecyl ether, ditetradecyl ether, hexadecyl ether, butyl methyl ether, butyl ethyl ether, butyl propyl ether, tert-butyl methyl ether, tert-butyl ethyl ether, tert-butylpropyl ether, di-tert-butyl ether, cyclopentylmethyl ether, cyclohexylmethyl ether, cyclopentylethyl ether, cyclohexylethyl ether, cyclopentylpropyl ether, cyclopentyl-2-propyl ether, cyclohexylpropyl ether, cyclohexyl-2-propyl ether, cyclopentylbutyl ether, cyclopentyl-tert-butyl ether, cyclohexylbutyl ether, cyclohexyl-tert-butyl ether, 2-octanone, 4-heptanone, and/or a (e.g., any suitable) combination thereof.

The ether-based solvent may have sufficient solubility or dispersibility for the aforementioned composition (e.g., copolymer).

In one or more embodiments, the resist topcoat composition may further include at least one other polymer selected from among an epoxy-based resin, a novolac resin, a glycoluril-based resin, and a melamine-based resin, but the present disclosure is not limited thereto.

The resist topcoat composition may further include an additive including a surfactant, a thermal acid generator, a plasticizer, and/or a (e.g., any suitable) combination thereof.

The surfactant may be, for example, an alkylbenzene sulfonic acid salt, an alkyl pyridinium salt, polyethylene glycol, a quaternary ammonium salt, and/or the like, but the present disclosure is not limited thereto.

The thermal acid generator may include (e.g., may be), for example, an acid compound such as p-toluene sulfonic acid, trifluoromethanesulfonic acid, pyridinium p-toluene sulfonic acid, salicylic acid, sulfosalicylic acid, citric acid, benzoic acid, hydroxybenzoic acid, and/or naphthalene carboxylic acid, benzoin tosylate, 2-nitrobenzyl tosylate, and other organic sulfonic acid alkyl esters, but the present disclosure is not limited thereto.

The amount of these additives utilized can be easily adjusted according to desired or suitable physical properties and may not be provided.

In one or more embodiments, a method of forming (or providing) patterns utilizing the aforementioned photoresist topcoat composition may be provided. In some embodiments, the manufactured pattern may be a photoresist pattern.

A method of forming (or providing) patterns according to some example embodiments includes coating and heating a photoresist composition on a substrate to form (or provide) a photoresist film, coating and heating the aforementioned photoresist topcoat composition on the photoresist film to form (or provide) a topcoat, and exposing and developing the topcoat and the photoresist film to form (or provide) a resist pattern.

Hereinafter, a method of forming (or providing) patterns utilizing the aforementioned photoresist topcoat composition will be described with reference to the drawing. The drawing is a schematic view for explaining a method of forming (or providing) patterns utilizing a photoresist topcoat composition according to the present disclosure. Here, the listing of the process in a particular order should not necessarily means that the invention or claims require that particular order. That is, the general rule that unless the steps, tasks, or acts of a process (e.g., a method claim) actually recite an order, the steps, tasks, or acts should not be construed to require one.

Referring to the drawing, first, an object to be etched is prepared. An example of the object to be etched may be a thin film formed on a semiconductor substrate. Hereinafter, only the case where the object to be etched is a thin film will be described. The surface of the thin film is cleaned to remove contaminants remaining on the thin film. The thin film may be, for example, a silicon nitride film, a polysilicon film, or a silicon oxide film.

A photoresist composition is coated on the thin film and heated to form (or provide) a photoresist film 101 (1). Subsequently, the photoresist topcoat composition is coated on the photoresist film and heated to form (or provide) a photoresist topcoat 30(2).

The heating may be performed at a temperature of about 80° C. to about 500° C.

Then, the photoresist topcoat 30 and the photoresist film 101 are exposed to high-energy radiation.

For example, the high-energy radiation utilized in the exposure process may include light having a high-energy wavelength, such as EUV (Extreme Ultraviolet; wavelength: 13.5 nm) and/or E-Beam (electron beam).

A post-exposure heat treatment (PEB) is then performed. The post-exposure heat treatment may be performed at a temperature of about 80° C. to about 200° C. By performing the post-exposure heat treatment, the exposed region of the photoresist film, that is, the region not covered by the patterned mask is changed to be soluble (e.g., have a property of being soluble) in a developer, so that the exposed region has a different solubility from that of the unexposed region of the photoresist film.

A photoresist pattern 102b may be formed by dissolving and removing the photoresist film 101 corresponding to the exposed region and the photoresist topcoat 30 utilizing a developer (3).

For example, the developer may be an alkaline developer or a developer containing an organic solvent (hereinafter referred to as an organic-based developer).

As the alkaline developer, a quaternary ammonium salt such as tetramethylammonium hydroxide may be utilized, but aqueous alkaline solutions such as inorganic alkalis, primary to tertiary amines, alcohol amines, and/or cyclic amines may also be utilized.

In some embodiments, the alkaline developer may contain alcohol and/or surfactant in an appropriate or suitable amount. An alkaline concentration of the alkaline developer may be, for example, about 0.1 to about 20 mass %, and a pH of the alkaline developer may be, for example, about 10 to about 15.

The organic-based developer may be a developer containing at least one organic solvent selected from the group consisting of ketone solvents, ester solvents, alcohol solvents, amide solvents, ether solvents, and hydrocarbon solvents.

Examples of the ketone solvent may include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonyl acetone, ionone, diacetonyl alcohol, acetyl carbinol, acetophenone, methyl naphthyl ketone, isophorone, propylene carbonate, and/or the like.

Examples of the ester solvent may include methyl acetate, butyl acetate, ethyl acetate, isopropyl acetate, pentyl acetate, isopentyl acetate, amyl acetate, propylene glycol monomethyl ether acetate, and ethylene glycol monoethyl ether acetate., ethylene glycol monobutyl ether acetate, ethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, butyl propionate, and/or the like.

Any suitable alcohol solvents, amide solvents, ether solvents, and hydrocarbon solvents may be utilized.

In some embodiments, a plurality of said solvents may be mixed, or may be mixed with solvents or water other than the above-described solvents. A moisture content (e.g., amount) as a whole of the developer may be desirably less than about 50 wt %, less than about 20 wt %, or less than about 10 wt %, and in an embodiment, the developer may be substantially free of moisture.

A content (e.g., amount) of the organic solvent may be desirably about 50 wt % to about 100 wt %, about 80 wt % to about 100 wt %, or about 90 wt % to about 100 wt %, and in an embodiment, about 95 wt % to about 100 wt % based on a total amount of the organic developer.

The organic developer may include an appropriate or suitable amount of a suitable surfactant as desired or required.

A content (e.g., amount) of the surfactant may be usually about 0.001 wt % to about 5 wt %, desirably about 0.005 wt % to about 2 wt %, or about 0.01 wt % to about 0.5 wt % based on a total amount of the developer.

In some embodiments, the organic developer may include an inhibitor.

Subsequently, the exposed thin film is etched by applying the photoresist pattern 102b as an etching mask. As a result, the thin film is formed into a thin film pattern.

The thin film may be etched, for example, by dry etching utilizing an etching gas, and the etching gas may be, for example, CHF₃, CF₄, Cl₂, BCl₃, or a mixture thereof.

In the exposure process performed above, the thin film pattern formed utilizing the photoresist pattern 102b that is formed by the exposure process performed utilizing the EUV light source may have a width corresponding to the photoresist pattern 102b. In some embodiments, the photoresist pattern 102b may have a width of about 5 nanometer (nm) to about 100 nm. In some embodiments, the thin film pattern formed by the exposure process performed utilizing an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, similar to that of the photoresist pattern 102b, and in an embodiment, the thin film pattern may be formed to have a width of less than or equal to about 20 nm.

Hereinafter, the present disclosure will be described in more detail through examples relating to the synthesis of the aforementioned polymer and the preparation of a photoresist topcoat composition including the same. However, the present disclosure is not technically limited by the following examples.

### SYNTHESIS EXAMPLES

### Synthesis Example 1: Synthesis of Compound 1a

20 g (59.86 mmol) of hexafluoro-2,3-bis(trifluoromethyl)-2,3-butanediol(perfluoropinacol), 7.79 g (59.86 mmol) of 2-(hydroxyethyl)methacrylate, and 18.84 g (71.84 mmol) of triphenylphosphine (PH3P) were mixed in 110 mL of diethyl ether under a nitrogen atmosphere and then, stirred. After stirring for 30 minutes, the mixture was cooled down to 0° C., and another mixture of 14.52 g (71.84 mmol) of diisopropyl azodicarboxylate (DIAD) and 35 mL of diethyl ether was slowly added thereto over 2 hours. Subsequently, the obtained mixture was stirred at room temperature (23° C.) for 24 hours and then, concentrated. The concentrated mixture was dissolved in dichloromethane and then, treated through column chromatography by utilizing silica gel to separate a synthesized material. The separated material was distilled under a reduced pressure, obtaining 2-[3,3,3-trifluoro-2-hydroxy-1,1,2-tris(trifluoromethyl)propoxy]ethyl 2-methyl-2-propenoate represented by Chemical Formula 1a.

* ¹H-NMR (Acetone-d6): δ 1.90 (3H, t), 4.36 (4H, m), 5.63 (1H, t), 6.09 (1H, t), 8.34 (1H, s)

* ¹⁹F-NMR (Acetone-d6): δ-70.12 (6F, m), −65.38 (6F, m)

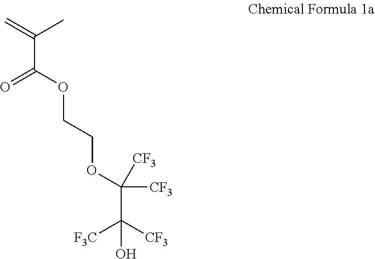 [SMILES: C=C(C)C(=O)OCCOC(C(F)(F)F)(C(F)(F)F)C(O)(C(F)(F)F)C(F)(F)F]

### Synthesis Example 2: Preparation of Copolymer (R1)

In a 250 mL 2-neck round bottom flask, a compound represented by Chemical Formula 1a (29.45 g, 66 mmol), a compound represented by Chemical Formula 1 b (DIHS (di-iodine hydroxyl styrene), Daejeong Chemical Co., Ltd.) (3.72 g, 10 mmol), a compound represented by Chemical Formula 1c (ethoxy ethoxy styrene, Tokyo Chemical Industry (TCI)) (4.61 g, 24 mmol), and 158 g of diisoamyl ether (DIAE) were added under a nitrogen atmosphere and then, heated to 100° C. When the internal temperature reached 100° C., 18.42 g of a 25 wt % V-601/DIAE solution (V-601, 4.61 g, 30 mmol) was slowly added thereto, and after 6 hours, the reaction solution was cooled to room temperature and then, concentrated to have a solid content (e.g., amount) of 50%. 270 g of heptane was added to the concentrated solution, and a polymer produced therefrom was filtered. The filtered polymer was completely dissolved in 34 g of DIAE, and 270 g of heptane was added thereto for precipitation, which were repeated twice to obtain precipitates, and the precipitates were completely dried, thereby preparing final Copolymer R1 (Mw=5,000).

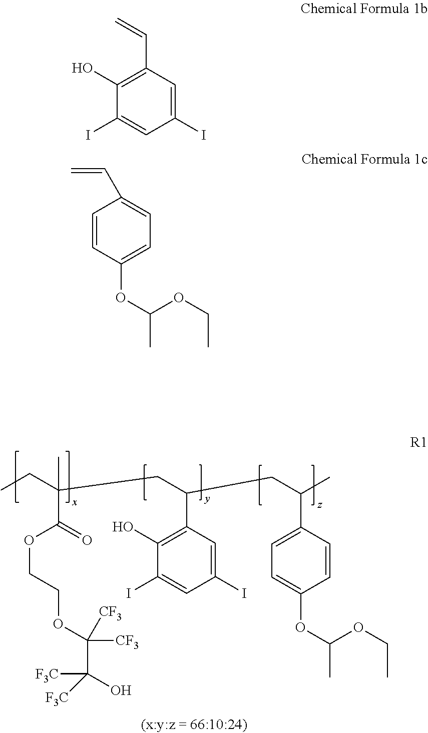

### Synthesis Example 3: Preparation of Copolymer (R2)

Copolymer R2 (Mw=4,500) was prepared in substantially the same manner as in Synthesis Example 2 except that the compound represented by Chemical Formula 2c (2-(4-Vinylphenoxy)tetrahydro-2H-pyran, Sigma-Aldrich Corporation) (6.77 g, 16 mmol) was utilized instead of the compound represented by Chemical Formula 1c.

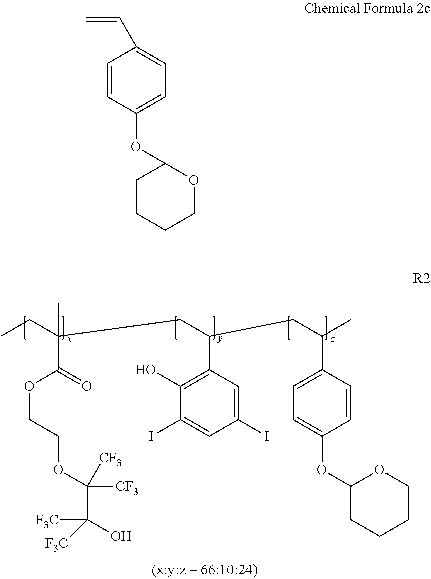

### Synthesis Example 4: Preparation of Copolymer R3

Copolymer R3 (Mw=5,500) was prepared in substantially the same manner as in Synthesis Example 2 except that the compound represented by Chemical Formula 2a (5,5,5-trifluoro-4-hydroxy-4-(trifluoromethyl)-2-pentanyl methacrylate, Sigma-Aldrich Corporation) (20.59 g, 70 mmol) instead of the compound represented by Chemical Formula 1a, the compound represented by Chemical Formula 1 b (di-iodine hydroxyl styrene (DIHS), Daejung Chemicals & Metals) (7.44 g, 20 mmol), and the compound represented by Chemical Formula 1c (ethoxy ethoxy styrene, TCI (Tokyo Chemical Industry)) (1.92 g, 10 mmol), and 124 g of diisoamyl ether (DIAE) were utilized.

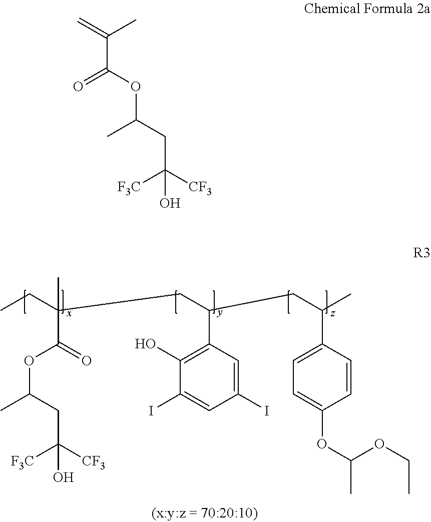

### Synthesis Example 5: Preparation of Copolymer R4

Copolymer R4 (Mw=4,700) was prepared in substantially the same manner as in Synthesis Example 4 except that the compound represented by Chemical Formula 2a (5,5,5-trifluoro-4-hydroxy-4-(trifluoromethyl)-2-pentanyl methacrylate, Sigma-Aldrich Corporation) (20.59 g, 70 mmol), the compound represented by Chemical Formula 1b (DIHS (di-iodine hydroxyl styrene), Daejung Chemicals & Metals) (3.72 g, 10 mmol), and the compound represented by Chemical Formula 2c (2-(4-vinylphenoxy)tetrahydro-2H-pyran, Sigma-Aldrich Corporation) (5.65 g, 20 mmol) were utilized.

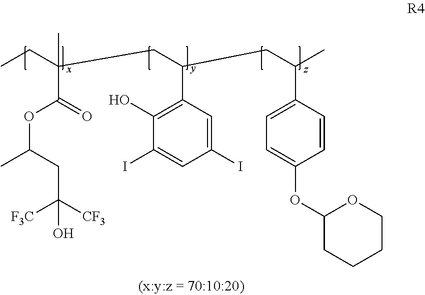

### Synthesis Example 6: Preparation of Copolymer R5

Copolymer R5 (Mw=5,900) was prepared in substantially the same manner as in Synthesis Example 2 except that the compound represented by Chemical Formula 3a (4,4,4-trifluoro-3-hydroxy-3-(trifluoromethyl)butyl methacrylate, Sigma-Aldrich Corporation) (19.33 g, 69 mmol) instead of the compound represented by Chemical Formula 1a, the compound represented by Chemical Formula 1b (DIHS (di-iodine hydroxyl styrene, Daejung Chemicals & Metals) (4.46 g, 12 mmol), the compound represented by Chemical Formula 1c (ethoxy ethoxy styrene, TCI (Tokyo Chemical Industry)) (3.65 g, 19 mmol), and 114 g of diisoamyl ether (DIAE) were utilized.

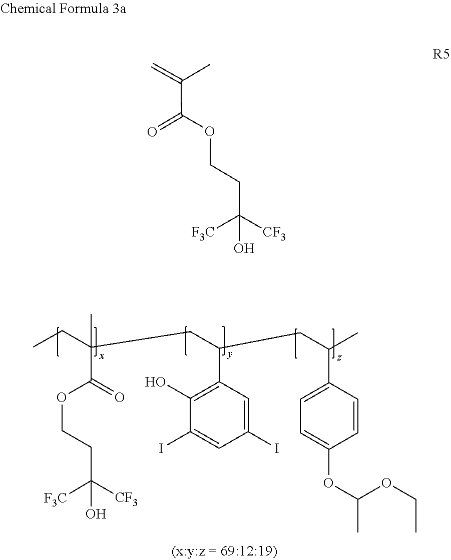

### Synthesis Example 7: Preparation of Copolymer R6

Copolymer R6 (Mw=4,700) was prepared in substantially the same manner as in Synthesis Example 3 except that the compound represented by Chemical Formula 3a (4,4,4-trifluoro-3-hydroxy-3-(trifluoromethyl)butyl methacrylate, Sigma-Aldrich Corporation) (19.33 g, 69 mmol) instead of the compound represented by Chemical Formula 1a, the compound represented by Chemical Formula 1b (DIHS (di-iodine hydroxyl styrene, Daejung Chemicals & Metals) (4.46 g, 12 mmol), and the compound represented by Chemical Formula 2c (2-(4-vinylphenoxy)tetrahydro-2H-pyran, Sigma-Aldrich Corporation) (5.36 g, 19 mmol), and 121 g of diisoamyl ether (DIAE) were utilized.

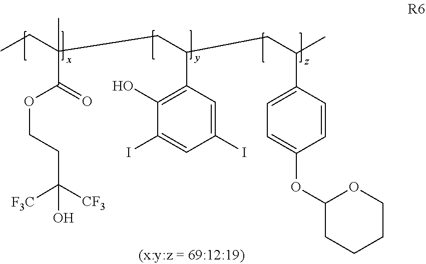

### Comparative Synthesis Example 1: Preparation of Copolymer R7

Copolymer R7 (Mw=4,000) was prepared in substantially the same manner as in Synthesis Example 2 except that the compound represented by Chemical Formula 2b (29.38 g, 79 mmol) and the compound represented by Chemical Formula 1c (4.04 g, 21 mmol) were utilized, but the compound represented by Chemical Formula 1a was not utilized.

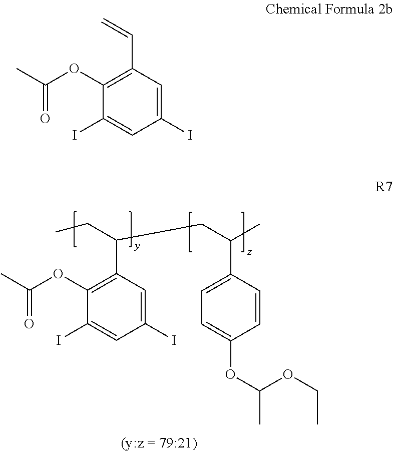

### Comparative Synthesis Example 2: Preparation of Copolymer R8

Copolymer R8 (Mw=4,000) was prepared in substantially the same manner as in Synthesis Example 2 except that the compound represented by Chemical Formula 2b (23.51 g, 79 mmol) and the compound represented by Chemical Formula 2c (4.74 g, 21 mmol) were utilized, but the compound represented by Chemical Formula 1a was not utilized.

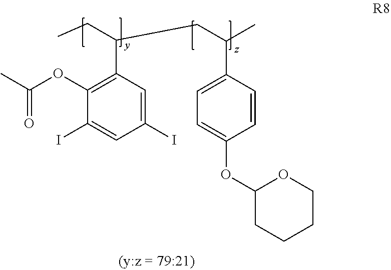

### Comparative Synthesis Example 3: Preparation of Copolymer R9

Copolymer R9 (Mw=4,500) was prepared in substantially the same manner as in Synthesis Example 2 except that the compound represented by Chemical Formula 1 b (21.94 g, 59 mmol) and the compound represented by Chemical Formula 1c (7.88 g, 41 mmol) were utilized, but the compound represented by Chemical Formula 1a was not utilized.

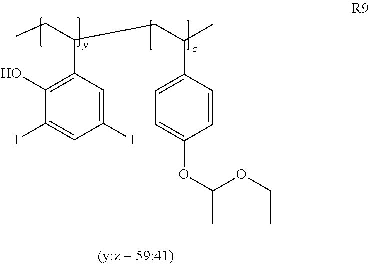

### Comparative Synthesis Example 4: Preparation of Copolymer R10

Copolymer R10 (Mw=4,500) was prepared in substantially the same manner as in Synthesis Example 2 except that the compound represented by Chemical Formula 1 b (17.56 g, 59 mmol) and the compound represented by Chemical Formula 2c (9.26 g, 41 mmol) were utilized, but the compound represented by Chemical Formula 1a was not utilized.

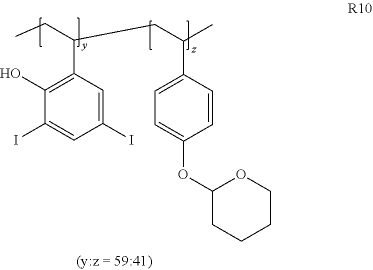

### Comparative Synthesis Example 5: Preparation of Copolymer R11

Copolymer R11 (Mw=5,500) was prepared in substantially the same manner as in Synthesis Example 2 except that the compound represented by Chemical Formula 1a (28.2 g, 79 mmol) and the compound represented by Chemical Formula 1c (3.23 g, 21 mmol) were utilized, but the compound represented by Chemical Formula 1 b was not utilized.

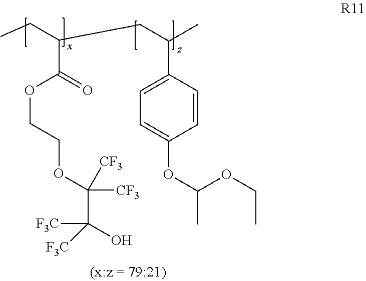

### Comparative Synthesis Example 6: Preparation of Copolymer R12

Copolymer R12 (Mw=5,000) was prepared in substantially the same manner as in Synthesis Example 2 except that the compound represented by Chemical Formula 1a (28.2 g, 79 mmol) and the compound represented by Chemical Formula 2c (4.74 g, 21 mmol) were utilized, but the compound represented by Chemical Formula 1 b was not utilized.

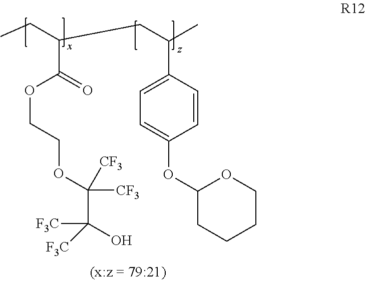

### Comparative Synthesis Example 7: Preparation of Copolymer R13

Copolymer R13 (Mw=5,500) was prepared in substantially the same manner as in Synthesis Example 2 except that the compound represented by Chemical Formula 2a (17.36 g, 59 mmol) and the compound represented by Chemical Formula 1c (7.88 g, 49 mmol) were utilized, but the compound represented by Chemical Formula 1 b was not utilized.

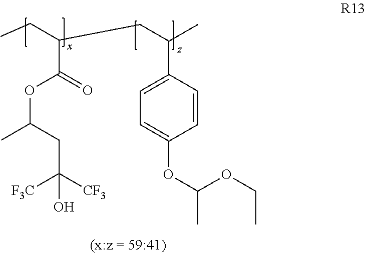

### Comparative Synthesis Example 8: Preparation of Copolymer R14

Copolymer R14 (Mw=5,000) was prepared in substantially the same manner as in Synthesis Example 2 except that the compound represented by Chemical Formula 2a (17.36 g, 59 mmol) and the compound represented by Chemical Formula 2c (11.57 g, 41 mmol) were utilized, but the compound represented by Chemical Formula 1 b was not utilized.

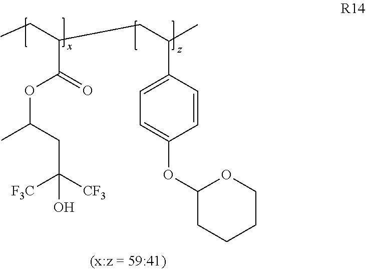

### Comparative Synthesis Example 9: Preparation of Copolymer R15

Copolymer R15 (Mw=5,000) was prepared in substantially the same manner as in Synthesis Example 2 except that the compound represented by Chemical Formula 1a (21.06 g, 59 mmol) and the compound represented by Chemical Formula 1 b (12.20 g, 41 mmol) were utilized, but the compound represented by Chemical Formula 1c was not utilized.

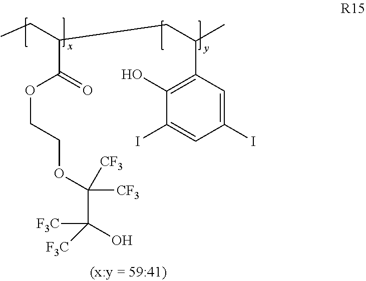

### Preparation of Resist Topcoat Compositions

### Example 1

0.5 wt % of Copolymer R1 according to Synthesis Example 2 was dissolved in 100 g of DIAE and then, stirred at room temperature (23° C.) for 24 hours and filtered through a TEFLON (tetrafluoroethylene) filter with a pore size of 0.45 μm, thereby preparing a resist topcoat composition according to Example 1.

### Examples 2 to 6 and Comparative Examples 1 to 9

Each resist topcoat composition was prepared in substantially the same manner as in Example 1 except that the copolymers according to Synthesis Examples 3 to 7 and Comparative Synthesis Examples 1 to 9 were respectively utilized instead of Copolymer R1.

### Evaluation 1: Solubility Evaluation

1 g of each of the copolymers of Synthesis Examples 2 to 7 and Comparative Synthesis Examples 1 to 9 was added to 50 g of DIAE (2 wt %) and then, stirred for 24 hours and the obtained solution was examined with respect to whether or not precipitates were produced with naked eyes, and the results are shown in Table 1.

### Evaluation Criteria

Solubility ∘: No foreign substances, transparent liquid state

Solubility Δ: No precipitate, somewhat opaque

Solubility X: precipitates were generated or the solution was completely cloudy

### Evaluation 2: Developability Evaluation

Each of the photoresist topcoat compositions according to Examples 1 to 6 and Comparative Examples 1 to 9 was spin-coated on a silicon substrate and heat-treated at 110° C. on a hot plate for 1 minute, forming (or providing) an about 5 nm-thick photoresist topcoat. The substrate with a topcoat formed thereon was rinsed with 2.38% tetramethylammonium hydroxide aqueous solution and heat-treated again at 110° C. on the hot plate for 1 minute and then, measured with respect to a thickness change of the topcoat layer, and the results are shown in Table 1.

*Residual film after development (%)=[Topcoat thickness before development (nm)−Topcoat thickness after development (nm)]×100/Topcoat thickness before development (nm)

### Evaluation Criteria

∘: If the residual film after development (%) calculated utilizing the above Calculation Equation is 98% or more.

Δ: If the residual film after development (%) calculated utilizing the above Calculation Equation is 90% or more but less than 98%.

X: If the residual film after development (%) calculated utilizing the above Calculation Equation is less than 90%

### Evaluation 3: Evaluation of Sensitivity and LWR

After forming (or providing) a resist underlayer (thickness: 50 Å) and a photoresist thin film for E-Beam (a thickness: 700 Å) on an 8-inch silicon substrate, each of the photoresist topcoat compositions according to the examples and the comparative examples was spin-coated thereon and then, heat-treated at 110° C. for 1 minute on a hot plate to form (or provide) an about 5 nm-thick photoresist topcoat.

On the wafer on which the photoresist topcoat was formed, line and space patterns were formed in a focus-energy matrix (FEM) format utilizing F-Beam equipment (JEOL JBX-9300FS). Subsequently, optimum sensitivity capable of forming (or providing) a critical dimension (CD) of 50 nm was checked in an interpolation method, and the results are shown in Table 1.

After checking the optimum sensitivity, a line width roughness (LWR) distribution at the corresponding energy shot was measured by utilizing CD-SEM equipment made by Hitatchi Ltd., and the same patterns at 500 points were measured within the shot in order to obtain reliability of the distribution, and final average values thereof are shown in Table 1.

TABLE 1

| | Copol- | Solu- | Develop- | Sensitivity | LWR |
|---|---|---|---|---|---|
| | ymer | bility | ability | (μC/cm²) | (nm) |
| Example 1 | R1 | ◯ | ◯ | 34.5 | 2.0 |
| Example 2 | R2 | ◯ | ◯ | 36.0 | 2.1 |
| Example 3 | R3 | ◯ | ◯ | 35.0 | 2.0 |
| Example 4 | R4 | ◯ | ◯ | 34.5 | 2.0 |
| Example 5 | R5 | ◯ | ◯ | 37.5 | 1.8 |
| Example 6 | R6 | ◯ | ◯ | 36.5 | 1.9 |
| Comparative Example 1 | R7 | Δ | X | 38.0 | 3.0 |
| Comparative Example 2 | R8 | Δ | X | 38.5 | 3.0 |
| Comparative Example 3 | R9 | Δ | X | 38.0 | 2.8 |
| Comparative Example 4 | R10 | Δ | X | 38.0 | 2.7 |
| Comparative Example 5 | R11 | ◯ | Δ | 40.0 | 2.5 |
| Comparative Example 6 | R12 | Δ | ◯ | 40.5 | 2.7 |
| Comparative Example 7 | R13 | ◯ | Δ | 42.0 | 2.6 |
| Comparative Example 8 | R14 | Δ | ◯ | 43.5 | 2.7 |
| Comparative Example 9 | R15 | Δ | Δ | 40.5 | 2.5 |

Referring to Table 1, if (e.g., when) the resist topcoat composition according to an embodiment of the present disclosure was applied, excellent or suitable solubility, developability, and sensitivity were not only achieved, but as pattern deterioration was suppressed or reduced, an excellent or suitable LWR improvement effect was also obtained.

In contrast, the resist topcoat composition of the comparative examples exhibited relatively deteriorated developability and sensitivity and no LWR improvement effect.

The use of “may” when describing embodiments of the present invention refers to “one or more embodiments of the present invention.” As used herein, the term “substantially,” “about,” and similar terms are used as terms of approximation and not as terms of degree, and are intended to account for the inherent deviations in measured or calculated values that would be recognized by those of ordinary skill in the art. Moreover, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a), and 35 U.S.C. § 132(a).

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and equivalents thereof.

### REFERENCE NUMERALS

1: forming (or providing) a photoresist film
2: forming (or providing) a photoresist topcoat
3: exposing and developing the photoresist film and the photoresist topcoat to form (or provide) a resist pattern
30: photoresist topcoat
100: substrate
101: photoresist film
102b: photoresist pattern

What is claimed is:

1. A resist topcoat composition, comprising:
a copolymer comprising:
a first structural unit represented by Chemical Formula M-1,
a second structural unit represented by Chemical Formula M-2, and
a third structural unit represented by Chemical Formula M-3A or Chemical Formula M-3B; and
a solvent: 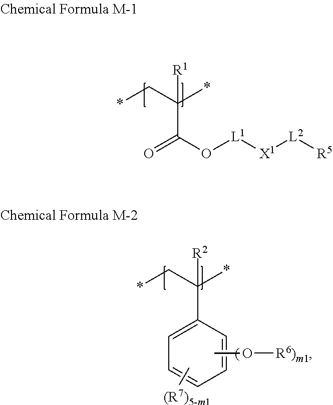
wherein, in Chemical Formula M-1 and Chemical Formula M-2,
R¹ and R² are each independently hydrogen or a substituted or unsubstituted C1 to C10 alkyl group,
L¹ and L² are each independently a single bond, or a substituted or unsubstituted C1 to C10 alkylene group,
X¹ is a single bond, —O—, —S—, —S(O)—, —S(O)₂—, —C(O)—, —C(═O)O—, —OC(═O)—, —OC(═O)O—, or —NR^{a}—, wherein R^{a} is hydrogen, deuterium, or a substituted or unsubstituted C1 to C10 alkyl group,
R⁵ is hydrogen, fluorine, a hydroxy group, or a substituted or unsubstituted C1 to C20 alkyl group,
R⁶ is hydrogen, or C(═O)R^{b},
R^{b} is a substituted or unsubstituted C1 to C10 alkyl group,
at least one of R⁵, L¹, or L² comprises fluorine and at least one of R⁵, L¹, or L² comprises a hydroxy group,
R⁷ is hydrogen, a halogen, a hydroxy group, or a substituted or unsubstituted C1 to C10 alkyl group, and
m1 is an integer selected from 1 to 4, 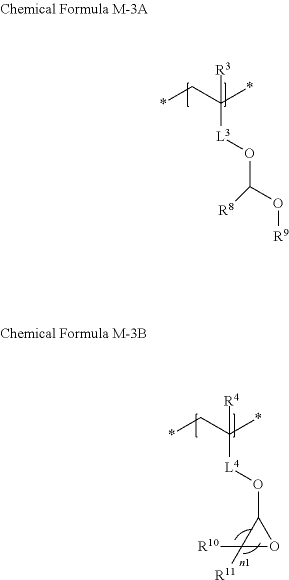
wherein, in Chemical Formula M-3A and Chemical Formula M-3B,
R³ and R⁴ are each independently hydrogen or a substituted or unsubstituted C1 to C10 alkyl group,
L³ and L⁴ are each independently a single bond, a substituted or unsubstituted C1 to C10 alkylene group, or a substituted or unsubstituted C6 to C20 arylene group,
R⁸ to R¹¹ are each independently hydrogen, a substituted or unsubstituted C1 to C20 alkyl group, a substituted or unsubstituted C2 to C20 alkenyl group, a substituted or unsubstituted C2 to C20 alkynyl group, or a substituted or unsubstituted C6 to C20 aryl group,
n1 is an integer selected from 1 to 6, and
is a linking point.

2. The resist topcoat composition of claim 1, wherein
the first structural unit is represented by Chemical Formula 1: 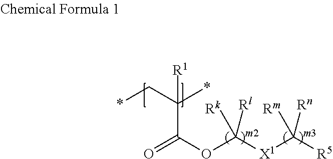
wherein, in Chemical Formula 1,
R¹ is hydrogen or a substituted or unsubstituted C1 to C10 alkyl group,
R^{k}, R^{l}, R^{m}, Rⁿ, and R⁵ are each independently hydrogen, fluorine, a hydroxy group, or a substituted or unsubstituted C1 to C20 alkyl group,
m2 and m3 are each independently an integer selected from 1 to 10,
X¹ is a single bond, —O—, —S—, —S(O)—, —S(O)₂—, —C(O)—, —C(═O)O—, —OC(═O)—, —OC(═O)O—, or —NR^{a}—, R^{a} being hydrogen, deuterium, or a substituted or unsubstituted C1 to C10 alkyl group, and
at least one of R^{k}, R^{l}, R^{m}, Rⁿ, or R⁵ comprises fluorine and at least one of R^{k}, R^{l}, R^{m}, Rⁿ, or R⁵ comprises a hydroxy group.

3. The resist topcoat composition of claim 2, wherein
in Chemical Formula 1, at least one of R^{m}, Rⁿ, or R⁵ comprises fluorine and at least one of R^{m}, Rⁿ, or R⁵ comprises a hydroxy group.

4. The resist topcoat composition of claim 2, wherein
in Chemical Formula 1, at least one of R^{m} or Rⁿ is fluorine or a C1 to C10 alkyl group substituted with at least one fluorine, and
R⁵ is a hydroxy group or a C1 to C10 alkyl group substituted with at least one hydroxy group.

5. The resist topcoat composition of claim 2, wherein
in Chemical Formula 1, at least one of R^{m} or Rⁿ is a hydroxy group or a C1 to C10 alkyl group substituted with at least one hydroxy group, and
R⁵ is fluorine or a C1 to C10 alkyl group substituted with at least one fluorine.

6. The resist topcoat composition of claim 2, wherein
in Chemical Formula 1, R^{m} is a hydroxy group or a C1 to C10 alkyl group substituted with at least one hydroxy group,
Rⁿ is fluorine or a C1 to C10 alkyl group substituted with at least one fluorine, and
R⁵ is a hydroxy group, fluorine, or a C1 to C10 alkyl group substituted with at least one of fluorine or hydroxy groups.

7. The resist topcoat composition of claim 2, wherein
in Chemical Formula 1, at least one of R^{m} or Rⁿ is fluorine or a C1 to C10 alkyl group substituted with at least one fluorine, and
R⁵ is a hydroxy group or a C1 to C5 alkyl group substituted with at least one of a hydroxy group or a C1 to C5 fluoroalkyl group.

8. The resist topcoat composition of claim 1, wherein
the first structural unit is represented by any one selected from among structural units of Group I: 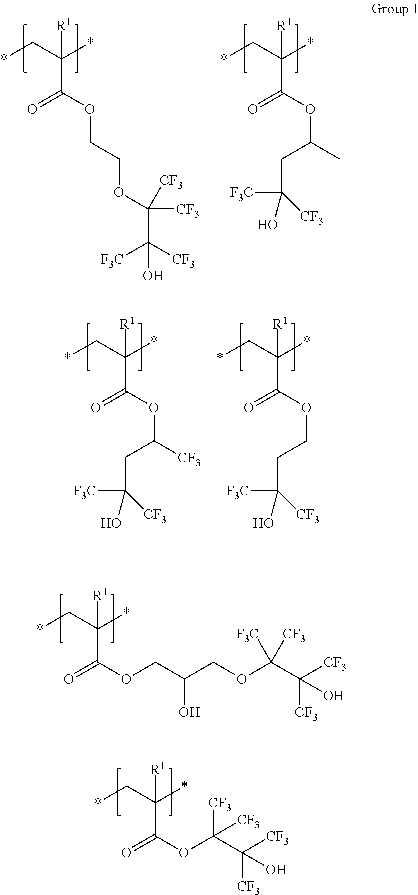
wherein, in Group I,
R¹ is each independently hydrogen or a methyl group, and
is a linking point.

9. The resist topcoat composition of claim 1, wherein
the second structural unit is represented by any one selected from among Chemical Formula 2-1 to Chemical Formula 2-4: 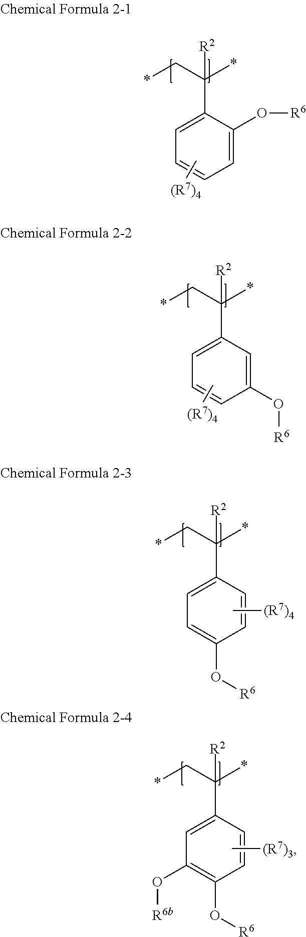
wherein, in Chemical Formula 2-1 to Chemical Formula 2-4,
R² is hydrogen or a methyl group,
R⁶, R^{6a}, and R^{6b} are each independently hydrogen, or C(═O)R^{b},
R^{b} is a substituted or unsubstituted C1 to C5 alkyl group,
R⁷ is each independently hydrogen, a halogen, a hydroxy group, or a substituted or unsubstituted C1 to C10 alkyl group, and
is a linking point.

10. The resist topcoat composition of claim 1, wherein
at least one of R⁷ is a halogen.

11. The resist topcoat composition of claim 1, wherein
at least one of R⁷ is an iodine group.

12. The resist topcoat composition of claim 1, wherein
the second structural unit is represented by any one selected from among structural units of Group II: 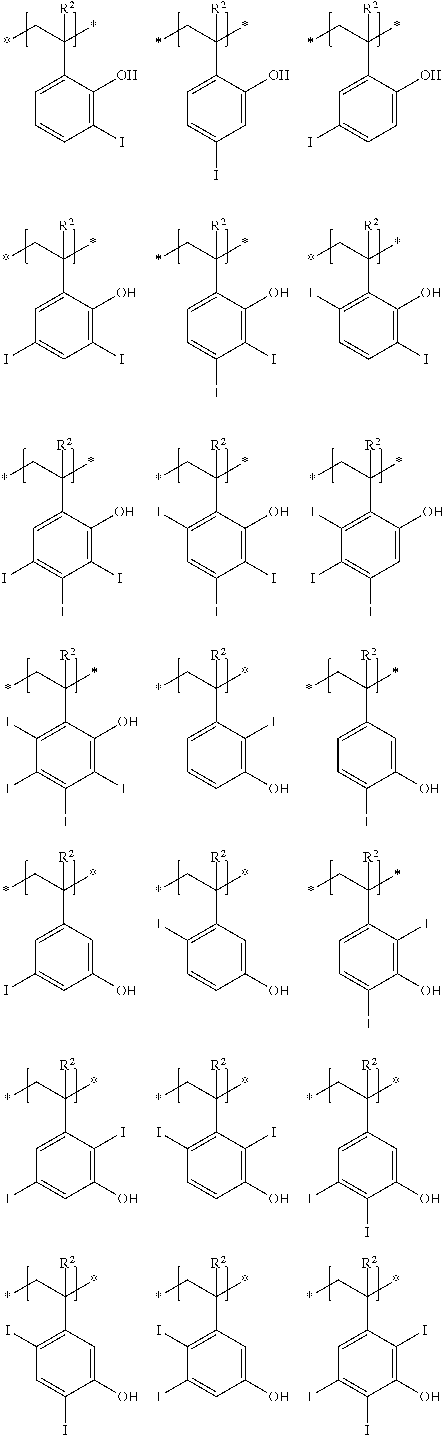 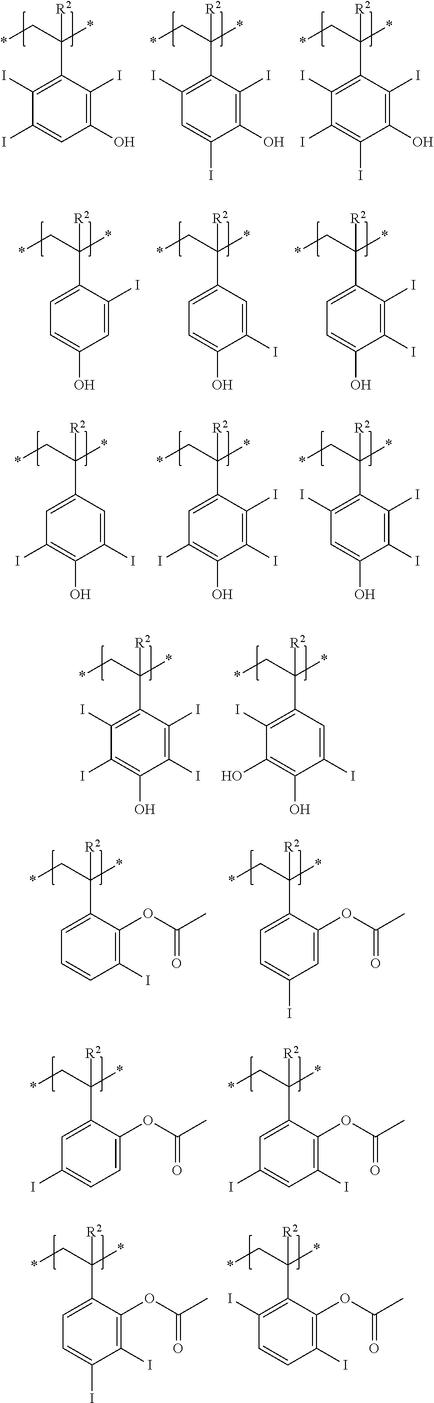 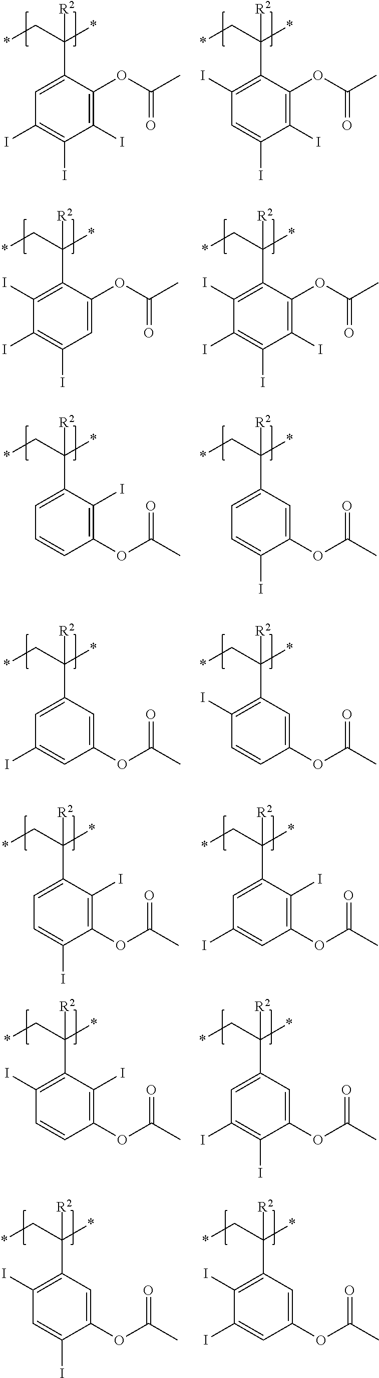 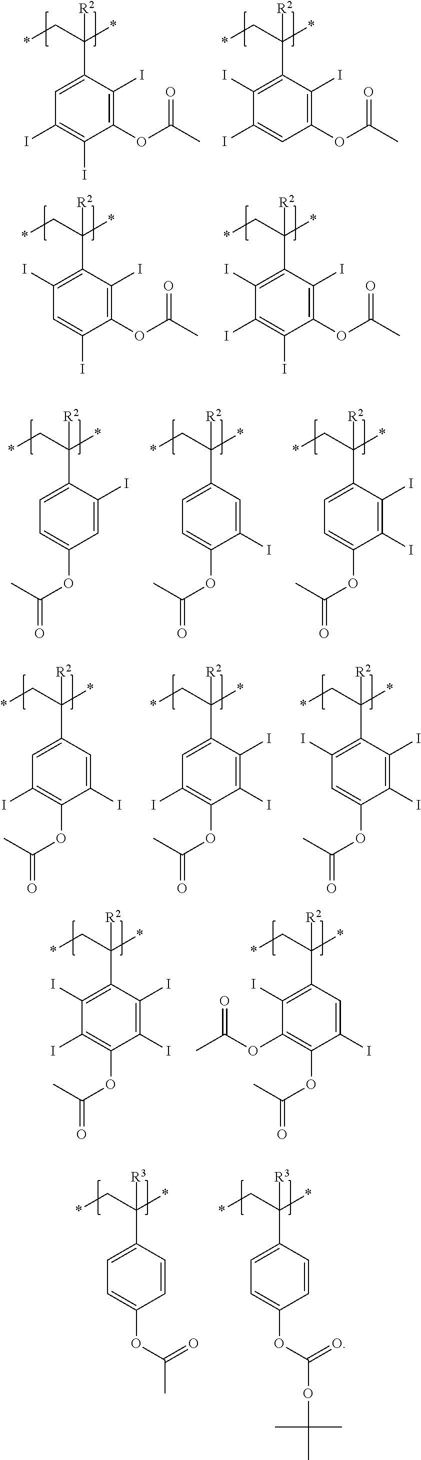
wherein, in Group II,
R² is each independently hydrogen or a methyl group, and
is a linking point.

13. The resist topcoat composition of claim 1, wherein
L³ and L⁴ are each independently a single bond, a substituted or unsubstituted C1 to C5 alkylene group, or a substituted or unsubstituted C6 to C12 arylene group, and
R⁸ to R¹¹ are each independently hydrogen, a substituted or unsubstituted C1 to C10 alkyl group, or a substituted or unsubstituted C6 to C12 aryl group.

14. The resist topcoat composition of claim 1, wherein
the third structural unit is represented by any one selected from among structural units of Group III: 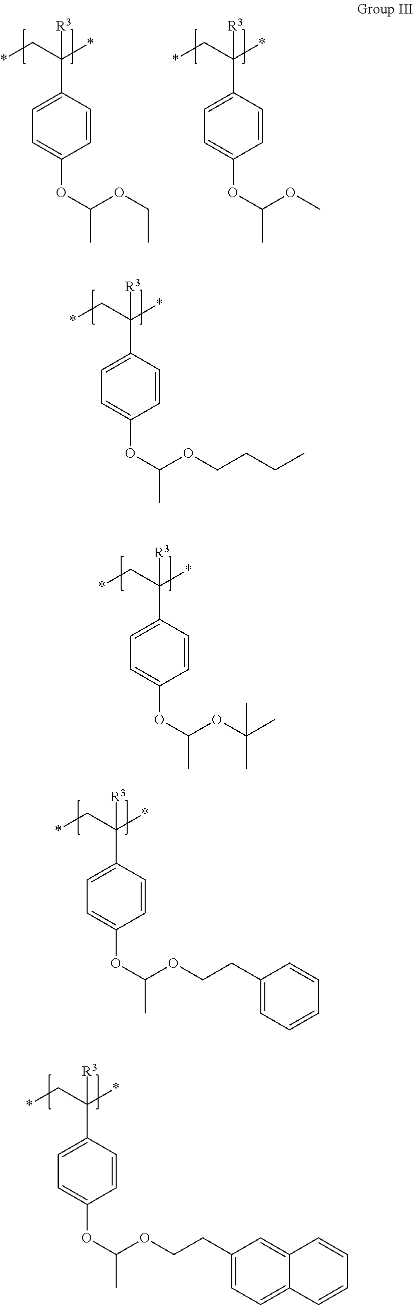 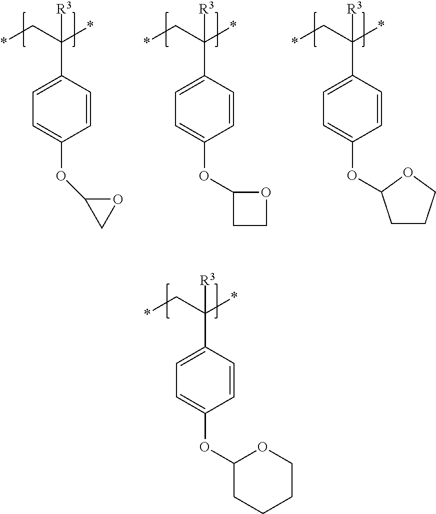
wherein, in Group III,
R³ is hydrogen or a methyl group, and
is a linking point.

15. The resist topcoat composition of claim 1, wherein
the copolymer comprises about 30 mol % to about 95 mol % of the first structural unit, about 1 mol % to about 30 mol % of the second structural unit, and about 1 mol % to about 40 mol % of the third structural unit.

16. The resist topcoat composition of claim 1, wherein
the copolymer has a weight average molecular weight (Mw) of about 1,000 g/mol to about 50,000 g/mol.

17. The resist topcoat composition of claim 1, wherein
the copolymer is about 0.1 wt % to about 10 wt % in amount based on a total weight of the resist topcoat composition.

18. The resist topcoat composition of claim 1, wherein
the solvent is an ether-based solvent represented by Chemical Formula 4: 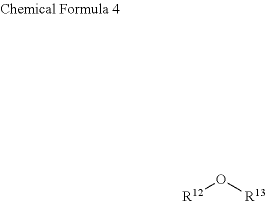
wherein, in Chemical Formula 4,
R¹² and R¹³ are each independently a substituted or unsubstituted C3 to C20 alkyl group.

19. A method of forming patterns, the method comprising:
coating and heating a photoresist composition on a substrate to form a photoresist film,
coating and heating the resist topcoat composition of claim 1 on the photoresist film to form a topcoat, and
exposing and developing the topcoat and the photoresist film to form a resist pattern.
